(19) United States
(12) Patent Application Publication
(10) Pub. No.: US 2020/0140592 A1
(43) Pub. Date: May 7, 2020

(54) PREPARATION OF POLYMER AND POLYMER

(71) Applicant: Shin-Etsu Chemical Co., Ltd., Tokyo (JP)

(72) Inventors: Teppei Adachi, Joetsu-shi (JP); Masayoshi Sagehashi, Joetsu-shi (JP); Emiko Ono, Joetsu-shi (JP); Hideyuki Onozuka, Joetsu-shi (JP)

(73) Assignee: Shin-Etsu Chemical Co., Ltd., Tokyo (JP)

(21) Appl. No.: 16/655,840

(22) Filed: Oct. 17, 2019

(30) Foreign Application Priority Data
Nov. 2, 2018 (JP) 2018-207176

(51) Int. Cl. C08F 220/18; G03F 7/038; G03F 7/039

(52) U.S. Cl. CPC C08F 220/18; G03F 7/2037; G03F 7/0397; G03F 7/0382

(57) ABSTRACT

A polymer comprising recurring units derived from a monomer (A) adapted to be decomposed to generate an acid upon light exposure, recurring units derived from a monomer (B) having an acid labile group, and recurring units derived from a monomer (C) having a phenolic hydroxyl group, an amount of residual monomer (A) in the polymer being up to 1.0 wt %, is prepared by feeding a monomer solution containing monomers (A), (B), and (C) in a solvent (S) to a reactor and effecting polymerization reaction in the reactor. The monomer solution has a monomer concentration of at least 35 wt %. The solvent (S) contains a compound having formula (S-1) or (S-2).

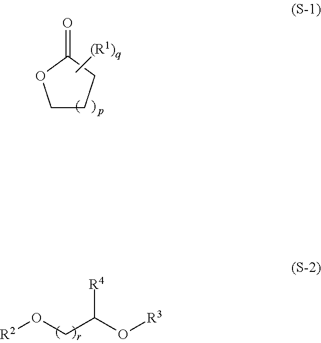

### CROSS-REFERENCE TO RELATED APPLICATION

This non-provisional application claims priority under 35 U.S.C. § 119(a) on Patent Application No. 2018-207176 filed in Japan on Nov. 2, 2018, the entire contents of which are hereby incorporated by reference.

### TECHNICAL FIELD

This invention relates to a method of preparing a polymer and a polymer.

### BACKGROUND ART

To meet the demand for higher integration density and operating speed of LSIs, the effort to reduce the pattern rule is in rapid progress. As the advanced miniaturization technology, microelectronic devices have been manufactured in a mass scale by the ArF immersion lithography wherein exposure is performed with water or similar liquid held between a projection lens and a substrate. Studies are made on the multiple patterning version of ArF lithography and the EUV lithography of wavelength 13.5 nm.

While chemically amplified resist compositions are generally used in the lithography, some resist compositions contain copolymers comprising units adapted to be decomposed to generate an acid upon light exposure (referred to as “acid generator units,” hereinafter) in addition to acid eliminatable units and lactone units incorporated as constituent units in conventional base resins. A base resin containing acid generator units is capable of suppressing acid diffusion because the acid generator units are incorporated as polymer pendant, which makes it possible to form a pattern at a high resolution. For example, the copolymers described in Patent Documents 1 to 4 are under study.

When such copolymers are prepared by prior art methods, monomers are not fully consumed. Then some monomers remain in the solution after polymerization or in the copolymer after purification. Particularly when acid generator units remain unreacted, the residual acid generator units allow for substantial acid diffusion as compared with the acid generator units which have been copolymerized and bound to the polymer backbone, failing to fully suppress acid diffusion. These resists are unsatisfactory with respect to various performance factors including resolution and pattern profile and especially edge roughness (LWR).

### CITATION LIST

Patent Document 1: JP-A 2011-070033
Patent Document 2: JP-A 2012-048075
Patent Document 3: WO 2013/111667
Patent Document 4: JP-A 2011-033839

### DISCLOSURE OF INVENTION

For the purpose of advancing further miniaturization, prior art base resins comprising acid generator units are not necessarily satisfactory with respect to various performance factors including resolution and pattern profile.

An object of the invention is to provide a method for preparing a polymer having a minimal amount of residual monomer and exhibiting satisfactory LWR when applied to resist compositions.

The inventors have found that when polymerization is carried out in a solvent having the formula (S-1) or (S-2) described below, a polymer containing a minimal amount of residual acid generator unit-providing monomer is obtained, that when the polymer is applied to EB or EUV lithography, satisfactory LWR is obtained, and that the polymer is quite effective for precise microfabrication.

In one aspect, the invention provides a method for preparing a polymer comprising recurring units derived from a monomer (A) adapted to be decomposed to generate an acid upon light exposure, recurring units derived from a monomer (B) having an acid labile group, and recurring units derived from a monomer (C) having a phenolic hydroxyl group, an amount of residual monomer (A) in the polymer being up to 1.0% by weight, the method comprising the steps of feeding a monomer solution containing monomer (A), monomer (B), and monomer (C) in a solvent (S) to a reactor and effecting polymerization reaction in the reactor. The monomer solution in the reactor has a monomer concentration of at least 35% by weight. The solvent (S) contains at least one compound selected from compounds having the following formulae (S-1) and (S-2):

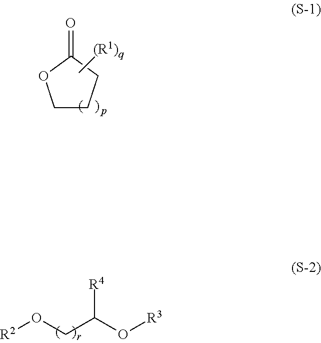

wherein R¹ is hydrogen, hydroxyl, or an optionally substituted C₁-C₈ alkyl group, R² to R⁴ are each independently hydrogen or an optionally substituted C₁-C₈ alkyl group, p is an integer of 1 to 3, q is an integer of 0 to 2, and r is an integer of 1 to 3.

Preferably, monomer (A) has the formula (A-1), (A-2) or (A-3).

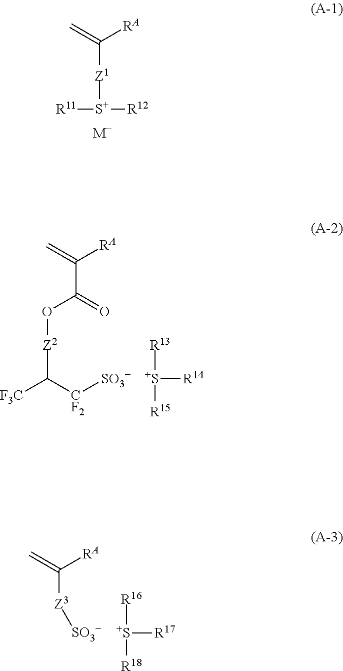

Herein R^{A} is each independently hydrogen or methyl; Z¹ is a single bond, phenylene, —O—Z¹¹—, —C(═O)—O—Z¹¹— or —C(═O)—NH—Z¹¹—, Z¹¹ is a C₁-C₆ alkanediyl group, C₂-C₆ alkenediyl group or phenylene group, which may contain a carbonyl moiety, ester bond, ether bond or hydroxyl moiety; Z² is a single bond or —Z²¹—C(═O)—O—, Z²¹ is a C₁-C₂₀ divalent hydrocarbon group which may contain a heteroatom; Z³ is a single bond, methylene, ethylene, phenylene, fluorinated phenylene, —O—Z³¹—, —C(═O)—O—Z³¹— or —C(═O)—NH—Z³¹—, Z³¹ is a C₁-C₆ alkanediyl group, C₂-C₆ alkenediyl group or phenylene group, which may contain a carbonyl moiety, ester bond, ether bond or hydroxyl moiety; R¹¹ to R¹⁸ are each independently a C₁-C₂₀ monovalent hydrocarbon group which may contain a heteroatom, R¹¹ and R¹² may bond together to form a ring with the sulfur atom to which they are attached, any two or more of R¹³, R¹⁴ and R¹⁵ may bond together to form a ring with the sulfur atom to which they are attached, any two or more of R¹⁶, R¹⁷ and R¹⁸ may bond together to form a ring with the sulfur atom to which they are attached; and M⁻ is a non-nucleophilic counter ion.

Preferably, monomer (B) has the formula (B-1) or (B-2).

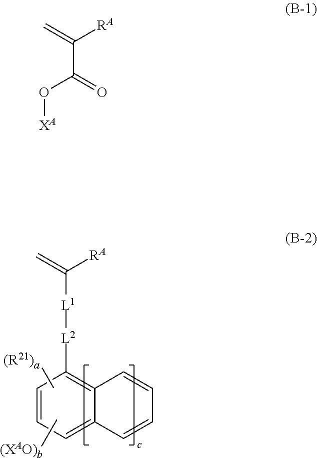

Herein R^{A} is each independently hydrogen or methyl, X^{A} is each independently an acid labile group, R²¹ is each independently hydrogen or a C₁-C₆ alkyl group which may contain an ether bond or carbonyl moiety, L¹ is a single bond, carbonyloxy group or amide group, L² is a single bond or C₁-C₇ alkanediyl group which may contain an ether bond or carbonyl moiety, a is an integer meeting a≤5+2c−b, b is an integer of 1 to 5, and c is an integer of 0 to 2.

Preferably, monomer (C) has the formula (C-1).

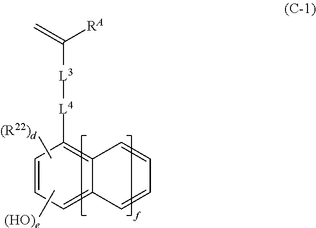

Herein R^{A} is each independently hydrogen or methyl, R²² is each independently hydrogen or a C₁-C₆ alkyl group which may contain an ether bond or carbonyl moiety, L³ is a single bond, carbonyloxy group or amide group, L⁴ is a single bond or C₁-C₇ alkanediyl group which may contain an ether bond or carbonyl moiety, d is an integer meeting d≤5+2f−e, e is an integer of 1 to 5, and f is an integer of 0 to 2.

Most preferably, the solvent having formula (S-1) is γ-butyrolactone, and the solvent having formula (S-2) is propylene glycol monomethyl ether.

Preferably, the amount of monomer (A) remaining in the reaction solution at the end of polymerization reaction is up to 1.5% by weight based on the polymer.

The method may further comprise the step of feeding an initiator solution to the reactor independently from the monomer solution.

The method may further comprise the step of adding the reaction solution to a poor solvent for purification after the polymerization reaction.

In another aspect, the invention provides a polymer comprising recurring units derived from a monomer (A) containing a structure adapted to be decomposed to generate an acid upon light exposure, recurring units derived from a monomer (B) having an acid labile group, and recurring units derived from a monomer (C) having a phenolic hydroxyl group, an amount of residual monomer (A) in the polymer being up to 1.0% by weight.

### Advantageous Effects of Invention

The method of preparing a polymer according to the invention succeeds in obtaining a polymer having a minimal amount of residual monomer. The resist composition comprising the polymer is suited for the EB or EUV lithography and achieves satisfactory LWR.

### DESCRIPTION OF EMBODIMENTS

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, the broken line designates a valence bond.

The abbreviations and acronyms have the following meaning.

EB: electron beam

EUV: extreme ultraviolet

Mw: weight average molecular weight

Mw/Mn: molecular weight distribution or dispersity

GPC: gel permeation chromatography

LWR: line width roughness

It is understood that for some structures represented by chemical formulae, there can exist enantiomers and diastereomers. In such a case, a single formula collectively represents all such isomers. The isomers may be used alone or in admixture.

The invention is directed to a method for preparing a polymer comprising recurring units derived from a monomer (A) adapted to be decomposed to generate an acid upon light exposure, recurring units derived from a monomer (B) having an acid labile group, and recurring units derived from a monomer (C) having a phenolic hydroxyl group, an amount of residual monomer (A) in the polymer being up to 1.0% by weight.

### Monomer (A)

Examples of monomer (A) adapted to be decomposed to generate an acid upon light exposure include monomers having the formulae (A-1) to (A-3).

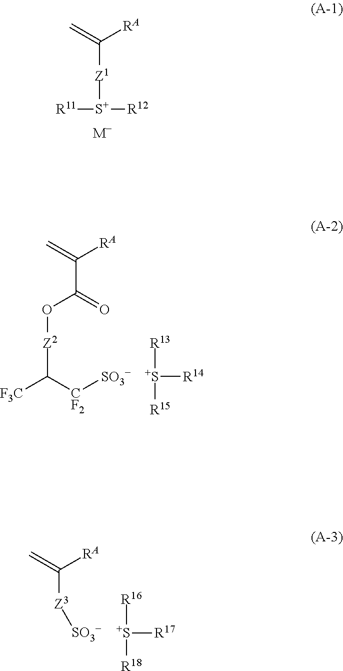

In formulae (A-1) to (A-3), R^{A} is each independently hydrogen or methyl. Z¹ is a single bond, phenylene, —O—Z¹¹—, —C(═O)—O—Z¹¹— or —C(═O)—NH—Z¹¹—, wherein Z¹¹ is a C₁-C₆ alkanediyl group, C₂-C₆ alkenediyl group or phenylene group, which may contain a carbonyl moiety (—CO—), ester bond (—COO—), ether bond (—O—) or hydroxyl moiety. Z² is a single bond or —Z²¹—C(═O)—O—, wherein Z²¹ is a C₁-C₂₀ divalent hydrocarbon group which may contain a heteroatom. Z³ is a single bond, methylene, ethylene, phenylene, fluorinated phenylene, —O—Z³¹—, —C(═O)—O—Z³¹— or —C(═O)—NH—Z³¹—, wherein Z³¹ is a C₁-C₆ alkanediyl group, C₂-C₆ alkenediyl group or phenylene group, which may contain a carbonyl moiety, ester bond, ether bond or hydroxyl moiety,

In formulae (A-1) to (A-3), R¹¹ to R¹⁸ are each independently a C₁-C₂₀ monovalent hydrocarbon group which may contain a heteroatom. The monovalent hydrocarbon group may be straight, branched or cyclic. Examples thereof include alkyl groups such as methyl, ethyl, n-propyl, isopropyl, n-butyl, tert-butyl, cyclopropyl, cyclopentyl, cyclohexyl, cyclopropylmethyl, 4-methylcyclohexyl, cyclohexylmethyl, norbomyl, adamantyl, alkenyl groups such as vinyl, allyl, propenyl, butenyl, hexenyl, cyclohexenyl, aryl groups such as phenyl, naphthyl and thienyl, and aralkyl groups such as benzyl, 1-phenylethyl, 2-phenylethyl, with the aryl groups being preferred. In these groups, some hydrogen may be substituted by a moiety containing a heteroatom such as oxygen, sulfur, nitrogen or halogen, or a moiety containing a heteroatom such as oxygen, sulfur or nitrogen may intervene between carbon atoms, so that the group may contain a hydroxyl moiety, cyano moiety, carbonyl moiety, ether bond, ester bond, sulfonic acid ester bond, carbonate bond, lactone ring, sultone ring, carboxylic anhydride (—C(═O)—O—C(═O)—), or haloalkyl moiety. R¹¹ and R¹² may bond together to form a ring with the sulfur atom to which they are attached, any two or more of R¹³, R¹⁴ and R¹⁵ may bond together to form a ring with the sulfur atom to which they are attached, any two or more of R¹⁶, R¹⁷ and R¹⁸ may bond together to form a ring with the sulfur atom to which they are attached.

In formula (A-1), M⁻ is a non-nucleophilic counter ion.

In formula (A-2), when Z² is —Z²¹—C(═O)—O— wherein Z²¹ is a C₁-C₂₀ divalent hydrocarbon group which may contain a heteroatom, examples of the divalent hydrocarbon group Z²¹ are shown below, but not limited thereto.

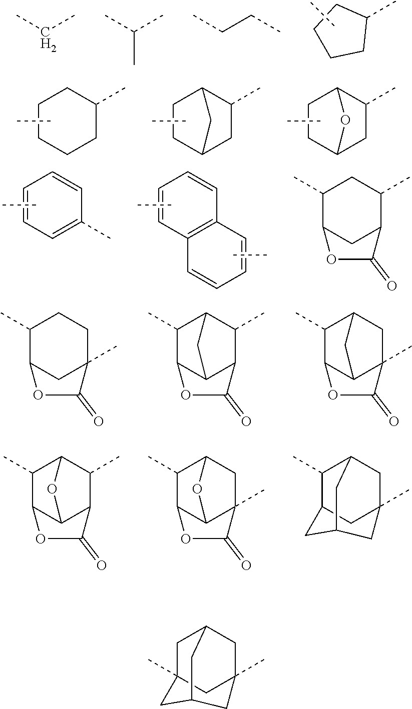

In formulae (A-2) and (A-3), when any two or more of R¹³, R¹⁴ and R¹⁵ bond together to form a ring with the sulfur atom to which they are attached, or when any two or more of R¹⁶, R¹⁷ and R¹⁸ bond together to form a ring with the sulfur atom to which they are attached, examples of the sulfonium cation are shown below, but not limited thereto.

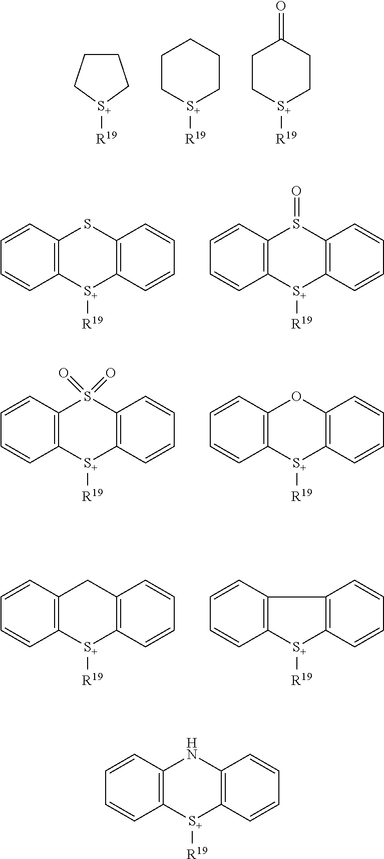

Herein, R¹⁹ is a group as defined for R¹¹ to R¹⁸.

In formulae (A-2) and (A-3), illustrative structures of the sulfonium cation are shown below, but not limited thereto.

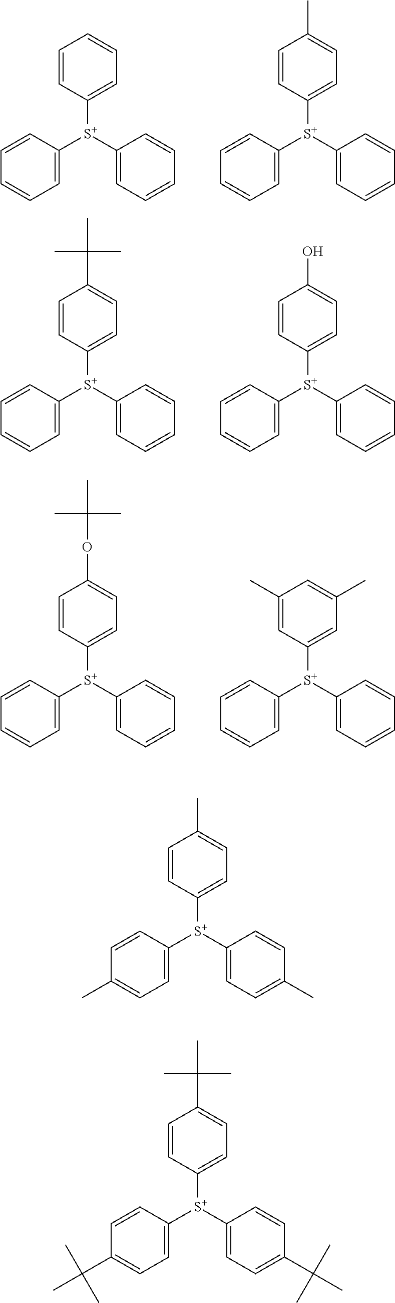

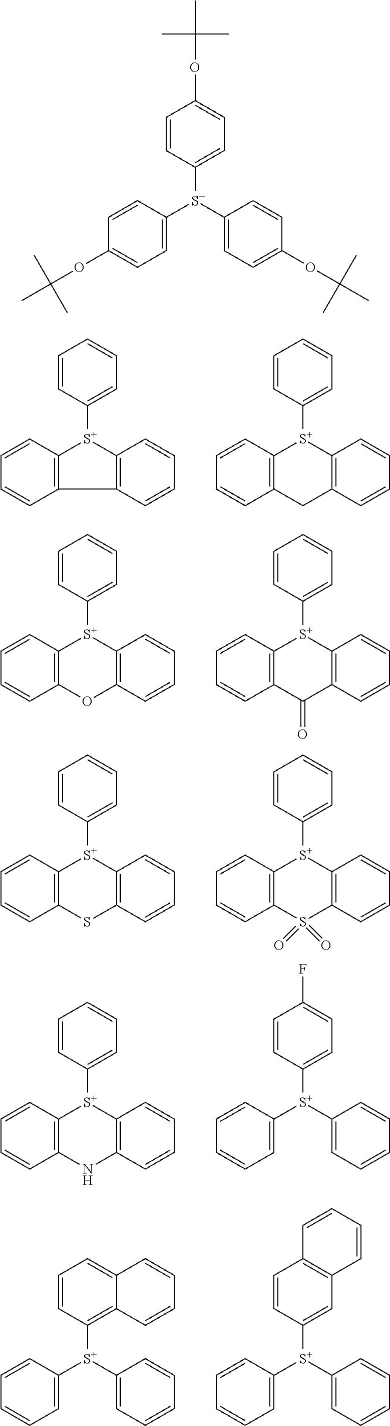

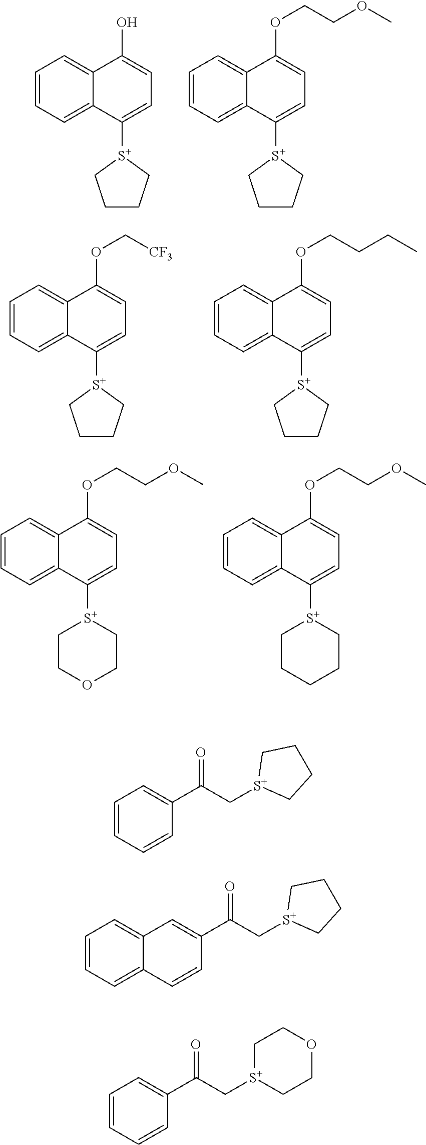

### Monomer (B)

Examples of monomer (B) having an acid labile group include monomers having the formulae (B-1) and (B-2).

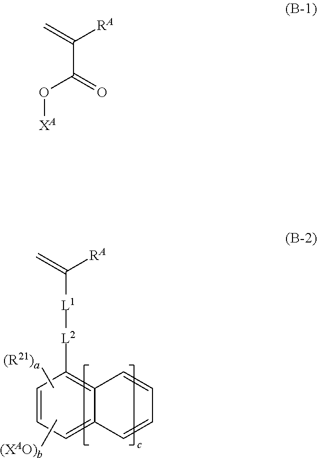

In formulae (B-1) and (B-2), R^{A} is as defined above. X^{A} is an acid labile group. R²¹ is each independently hydrogen or a C₁-C₆ alkyl group which may contain an ether bond or carbonyl moiety. L¹ is a single bond, carbonyloxy group or amide group. L² is a single bond or C₁-C₇ alkanediyl group which may contain an ether bond or carbonyl moiety. The subscript a is an integer meeting a≤5+2c−b, b is an integer of 1 to 5, and c is an integer of 0 to 2.

In formula (B-2), examples of the C₁-C₆ alkyl group which may contain an ether bond or carbonyl moiety, represented by R²¹, include methyl, ethyl, propyl, isopropyl, n-butyl, sec-butyl, tert-butyl, pentyl, hexyl, heptyl, octyl, cyclopentyl, cyclohexyl, and the groups shown below, but are not limited thereto.

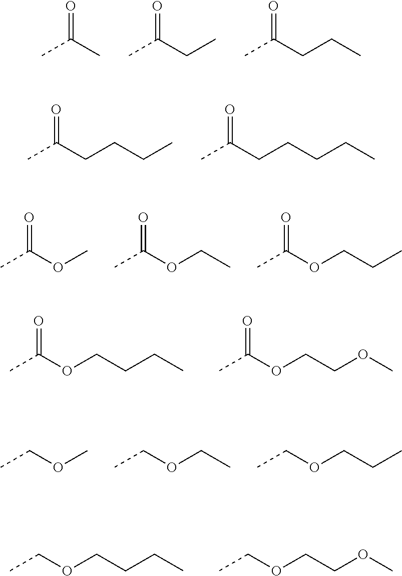

In formula (B-2), examples of the C₁-C₇ alkanediyl group which may contain an ether bond or carbonyl moiety, represented by L², include methylene, ethylene, propane-1,3-diyl, butane-1,4-diyl, pentane-1,5-diyl, hexane-1,6-diyl, heptane-1,7-diyl, and the groups shown below, but are not limited thereto.

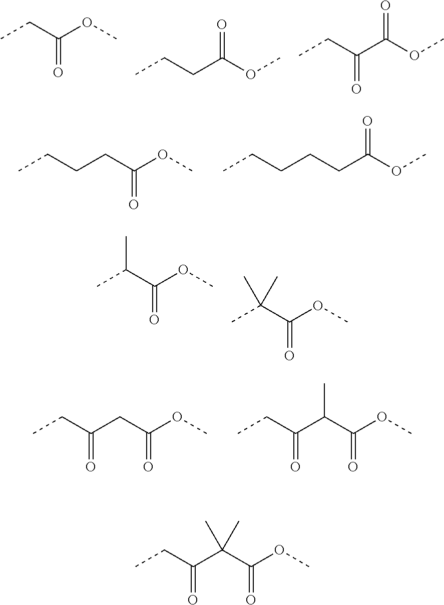

A polymer comprising recurring units derived from a monomer having formula (B-1) or (B-2) is decomposed under the action of an acid to generate a carboxyl or phenolic hydroxyl group so that it turns alkali soluble. The acid labile group X^{A} may be selected from various such groups, specifically groups having the following formulae (L1) to (L9), C₄-C₂₀, preferably C₄-C₁₅ tertiary alkyl groups, trialkylsilyl groups in which each alkyl moiety is of 1 to 6 carbon atoms, and C₄-C₂₀ oxoalkyl groups.

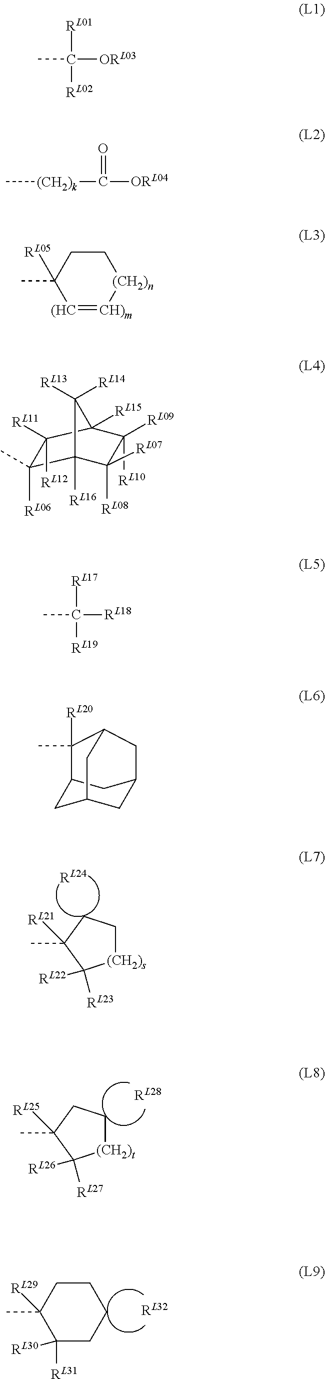

In formula (L1), R^{L01} and R^{L02} are each independently hydrogen or a C₁-C₁₈, preferably C₁-C₁₀ alkyl group. The alkyl group may be straight, branched or cyclic and examples thereof include methyl, ethyl, propyl, isopropyl, n-butyl, sec-butyl, tert-butyl, cyclopentyl, cyclohexyl, 2-ethylhexyl, n-octyl, norbornyl, tricyclodecanyl, tetracyclododecanyl, and adamantyl.

In formula (L1), R^{L03} is a C₁-C₁₈, preferably C₁-C₁₀ monovalent hydrocarbon group which may contain a heteroatom. Suitable heteroatoms include oxygen, nitrogen and sulfur. Examples of the monovalent hydrocarbon group include straight, branched or cyclic alkyl groups and substituted forms of the foregoing in which some hydrogen is substituted by hydroxyl, alkoxy, oxo, amino, alkylamino or the like, or some carbon is replaced by a moiety containing a heteroatom such as oxygen. Suitable alkyl groups are as exemplified above for R^{L01} and R^{L02}. Suitable substituted alkyl groups are shown below.

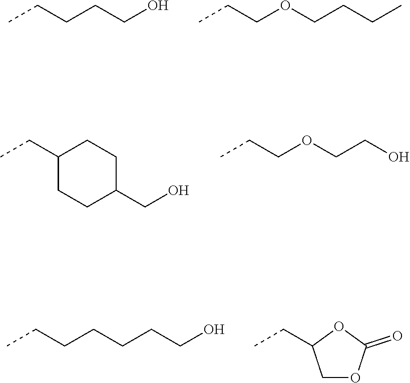

A pair of R^{L01} and R^{L02}, R^{L01} and R^{L03}, or R^{L02} and R^{L03} may bond together to form a ring with the carbon and oxygen atom to which they are attached. A ring-forming combination is a C₁-C₁₈, preferably C₁-C₁₀ straight or branched alkanediyl group.

In formula (L2), R^{L04} is a C₄-C₂₀, preferably C₄-C₁₅ tertiary alkyl group, trialkylsilyl group in which each alkyl moiety is of 1 to 6 carbon atoms, C₄-C₂₀ oxoalkyl group, or group having formula (L1), and k is an integer of 0 to 6.

Suitable tertiary alkyl groups include tert-butyl, tert-pentyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, and 2-ethyl-2-adamantyl. Suitable trialkylsilyl groups include trimethylsilyl, triethylsilyl, dimethyl-tert-butylsilyl. Suitable oxoalkyl groups include 3-oxocyclohexyl, 4-methyl-2-oxooxan-4-yl, and 5-methyl-2-oxooxolan-5-yl.

In formula (L3), R^{L05} is a C₁-C₈ alkyl group which may contain a heteroatom or a C₆-C₂₀ aryl group which may contain a heteroatom. The alkyl group may be straight, branched or cyclic and examples thereof include methyl, ethyl, propyl, isopropyl, n-butyl, sec-butyl, tert-butyl, n-pentyl, tert-pentyl, n-hexyl, cyclopentyl, and cyclohexyl. In these groups, some hydrogen may be substituted by hydroxyl, alkoxy, carboxyl, alkoxycarbonyl, oxo, amino, alkylamino, cyano, mercapto, alkylthio, sulfo or the like. Examples of the aryl group include phenyl, methylphenyl, naphthyl, anthryl, phenanthryl, and pyrenyl. In formula (L3), m is 0 or 1, n is an integer of 0 to 3, and 2m+n is equal to 2 or 3.

In formula (L4), R^{L06} is a C₁-C₁₀ alkyl group which may contain a heteroatom or a C₆-C₂₀ aryl group which may contain a heteroatom. Examples of the alkyl and aryl groups are the same as exemplified above for R^{L05}

In formula (L4), R^{L07} to R^{L16} are each independently hydrogen or a C₁-C₁₅ monovalent hydrocarbon group. The monovalent hydrocarbon group may be straight, branched or cyclic. Examples include straight, branched or cyclic alkyl groups such as methyl, ethyl, propyl, isopropyl, n-butyl, sec-butyl, tert-butyl, n-pentyl, tert-pentyl, n-hexyl, n-octyl, n-nonyl, n-decyl, cyclopentyl, cyclohexyl, cyclopentylmethyl, cyclopentylethyl, cyclopentylbutyl, cyclohexylmethyl, cyclohexylethyl and cyclohexylbutyl, and substituted forms of the foregoing in which some hydrogen is substituted by hydroxyl, alkoxy, carboxyl, alkoxycarbonyl, oxo, amino, alkylamino, cyano, mercapto, alkylthio, sulfo or the like. Alternatively, two of R^{L07} to R^{L16} may bond together to form a ring with the carbon atom to which they are attached (for example, a pair of R^{L07} and R^{L08}, R^{L07} and R^{L09}, R^{L08} and R^{L10}, R^{L09} and R^{L10}, R^{L11} and R^{L12}, R^{L13} and R^{L14}, or a similar pair). A ring-forming combination of R's is a C₁-C₁₅ divalent hydrocarbon group, examples of which are the ones exemplified above for the monovalent hydrocarbon groups, with one hydrogen atom being eliminated. Two of R^{L07} to R^{L16} which are attached to vicinal carbon atoms may bond together directly to form a double bond (for example, a pair of R^{L07} and R^{L09}, R^{L09} and R^{L15}, R^{L13} and R^{L15}, or a similar pair).

In formula (L5), R^{L17} to R^{L19} are each independently a C₁-C₁₅ alkyl group. The alkyl group may be straight, branched or cyclic and examples thereof include methyl, ethyl, propyl, isopropyl, n-butyl, sec-butyl, tert-butyl, cyclopentyl, cyclohexyl, 2-ethylhexyl, n-octyl, 1-adamantyl and 2-adamantyl.

In formula (L6), R^{L20} is a C₁-C₁₀ alkyl group which may contain a heteroatom or a C₆-C₂₀ aryl group which may contain a heteroatom. Examples of the alkyl and aryl groups are as exemplified above for R^{L05}.

In formula (L7), R^{L21} is a C₁-C₁₀ alkyl group which may contain a heteroatom or a C₆-C₂₀ aryl group which may contain a heteroatom. Examples of the alkyl and aryl groups are as exemplified above for R^{L05}. R^{L22} and R^{L23} are each independently hydrogen or a C₁-C₁₀ monovalent hydrocarbon group. The monovalent hydrocarbon group may be straight, branched or cyclic and examples thereof are as exemplified above for R^{L07} to R^{L16}, R^{L22} and R^{L23} may bond together to form a substituted or unsubstituted cyclopentane or cyclohexane ring with the carbon atom to which they are attached. R^{L24} is a divalent group which forms a substituted or unsubstituted cyclopentane, cyclohexane or norbomane ring with the carbon atom to which it is attached. The subscript s is 1 or 2.

In formula (L8), R^{L25} is a C₁-C₁₀ alkyl group which may contain a heteroatom or a C₆-C₂₀ aryl group which may contain a heteroatom. Examples of the alkyl and aryl groups are as exemplified above for R^{L05}. R^{L26} and R^{L27} are each independently hydrogen or a C₁-C₁₀ monovalent hydrocarbon group. The monovalent hydrocarbon group may be straight, branched or cyclic and examples thereof are as exemplified above for R^{L07} to R^{L16}, R^{L26} and R^{L27} may bond together to form a substituted or unsubstituted cyclopentane or cyclohexane ring with the carbon atom to which they are attached. R^{L28} is a divalent group which forms a substituted or unsubstituted cyclopentane, cyclohexane or norbomane ring with the carbon atom to which it is attached. The subscript t is 1 or 2.

In formula (L9), R^{L29} is a C₁-C₁₀ alkyl group which may contain a heteroatom or a C₆-C₂₀ aryl group which may contain a heteroatom. Examples of the alkyl and aryl groups are as exemplified above for R^{L05}. R^{L30} and R^{L31} are each independently hydrogen or a C₁-C₁₀ monovalent hydrocarbon group. The monovalent hydrocarbon group may be straight, branched or cyclic and examples thereof are as exemplified above for R^{L07} to R^{L16}, R^{L30} and R^{L31} may bond together to form a substituted or unsubstituted cyclopentane or cyclohexane ring with the carbon atom to which they are attached. R^{L32} is a divalent group which forms a substituted or unsubstituted cyclopentane, cyclohexane or norbomane ring with the carbon atom to which it is attached.

Of the acid labile groups having formula (L1), the straight and branched ones are exemplified by the following groups, but not limited thereto.

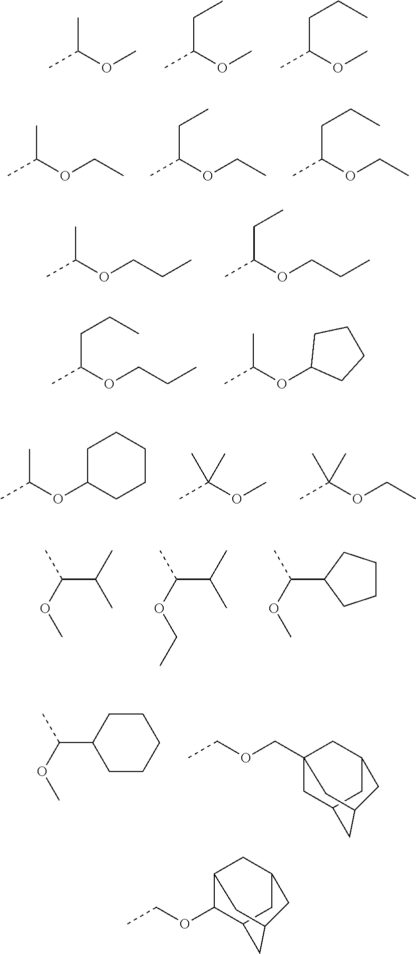

Of the acid labile groups having formula (L1), the cyclic ones are, for example, tetrahydrofuran-2-yl, 2-methyltetrahydrofuran-2-yl, tetrahydropyran-2-yl, and 2-methyltetrahydropyran-2-yl.

Examples of the acid labile group having formula (L2) include tert-butoxycarbonyl, tert-butoxycarbonylmethyl, tert-pentyloxycarbonyl, tert-pentyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl.

Examples of the acid labile group having formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-tert-butylcyclopentyl, 1-cyclohexylcyclopentyl, 1-(4-methoxy-n-butyl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, and 3-ethyl-1-cyclohexen-3-yl.

Of the acid labile groups having formula (L4), groups having the following formulae (L4-1) to (L4-4) are preferred.

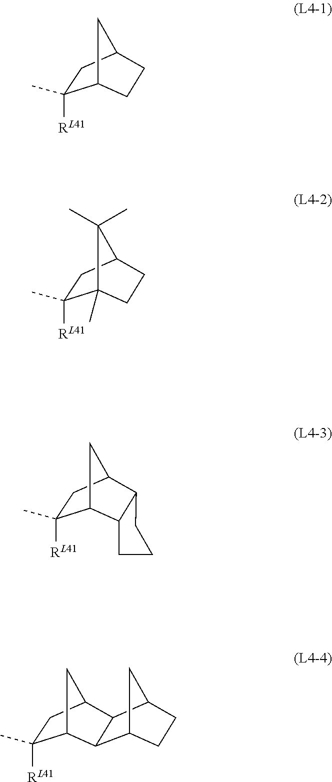

In formulas (L4-1) to (L4-4), the broken line denotes a bonding site and direction. R^{L41} is each independently a C₁-C₁₀ monovalent hydrocarbon group. The monovalent hydrocarbon group may be straight, branched or cyclic, and examples thereof include alkyl groups such as methyl, ethyl, propyl, isopropyl, n-butyl, sec-butyl, tert-butyl, n-pentyl, tert-pentyl, n-hexyl, cyclopentyl and cyclohexyl.

For formulae (L4-1) to (L4-4), there can exist stereoisomers (enantiomers or diastereomers). Each of formulae (L4-1) to (L4-4) collectively represents all such stereoisomers. When the acid labile group X^{A} is of formula (L4), there may be contained a plurality of stereoisomers.

For example, the formula (L4-3) represents one or a mixture of two selected from groups having the following formulas (L4-3-1) and (L4-3-2).

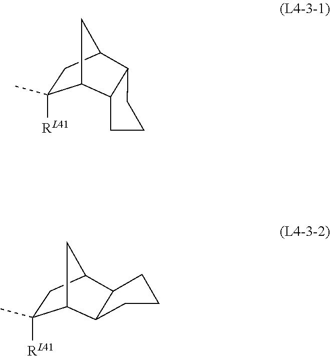

Herein R^{L41} is as defined above.

Similarly, the formula (L4-4) represents one or a mixture of two or more selected from groups having the following formulas (L4-4-1) to (L4-4-4).

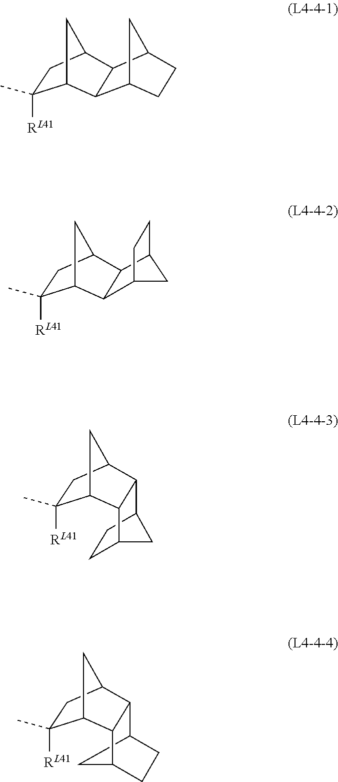

Herein R^{L41} is as defined above.

Each of formulas (L4-1) to (L4-4), (L4-3-1) and (L4-3-2), and (L4-4-1) to (L4-4-4) collectively represents an enantiomer thereof and a mixture of enantiomers.

It is noted that in the above formulas (L4-1) to (L4-4), (L4-3-1) and (L4-3-2), and (L4-4-1) to (L4-4-4), the bond direction is on the exo side relative to the bicyclo[2.2.1]heptane ring, which ensures high reactivity for acid catalyzed elimination reaction (see JP-A 2000-336121). In preparing these monomers having a tertiary exo-alkyl group of bicyclo[2.2.1]heptane skeleton as a substituent group, there may be contained monomers substituted with an endo-alkyl group as represented by the following formulas (L4-1-endo) to (L4-4-endo). For good reactivity, an exo proportion of at least 50 mol % is preferred, with an exo proportion of at least 80 mol % being more preferred.

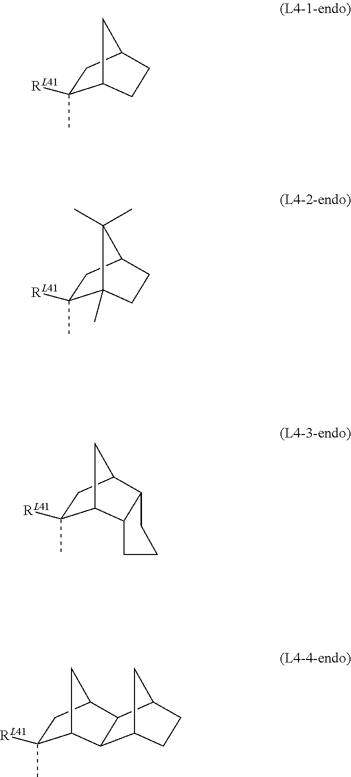

Herein RL⁴¹ is as defined above.

Illustrative, non-limiting examples of the acid labile group having formula (L4) are given below.

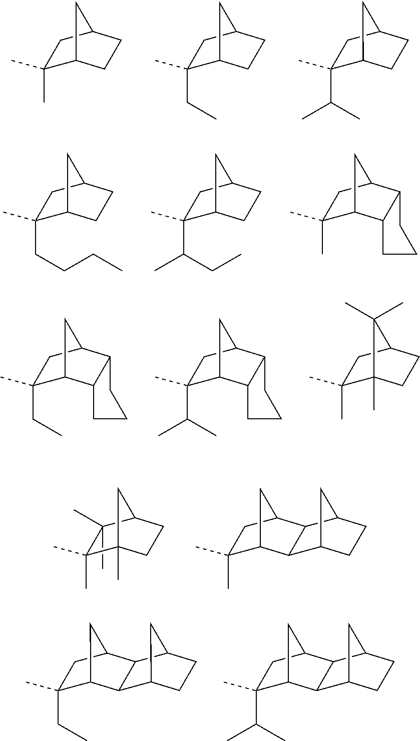

Illustrative, non-limiting examples of the acid labile group having formula (L5) are given below.

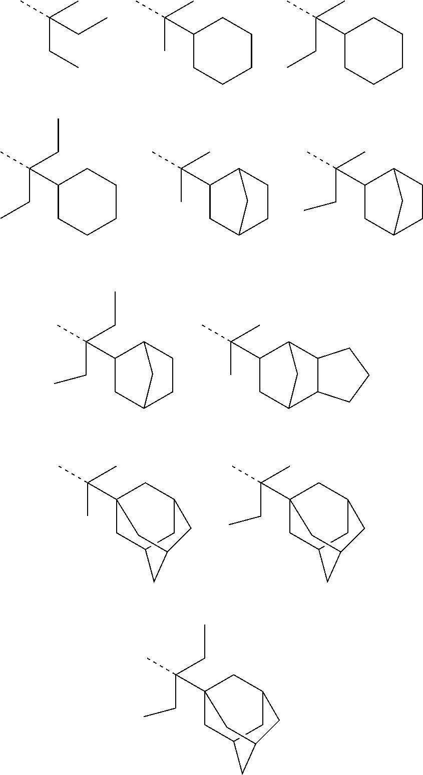

Illustrative, non-limiting examples of the acid labile group having formula (L6) are given below.

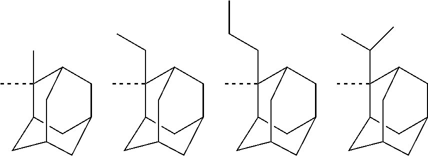

Illustrative, non-limiting examples of the acid labile group having formula (L7) are given below.

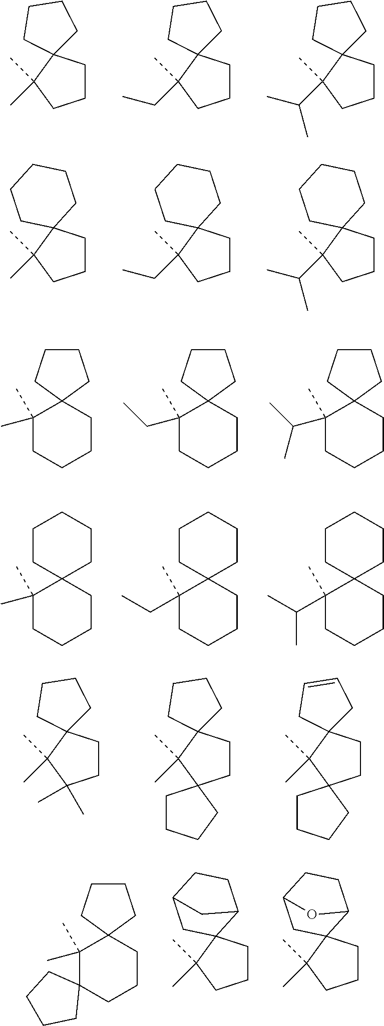

Illustrative, non-limiting examples of the acid labile group having formula (L8) are given below.

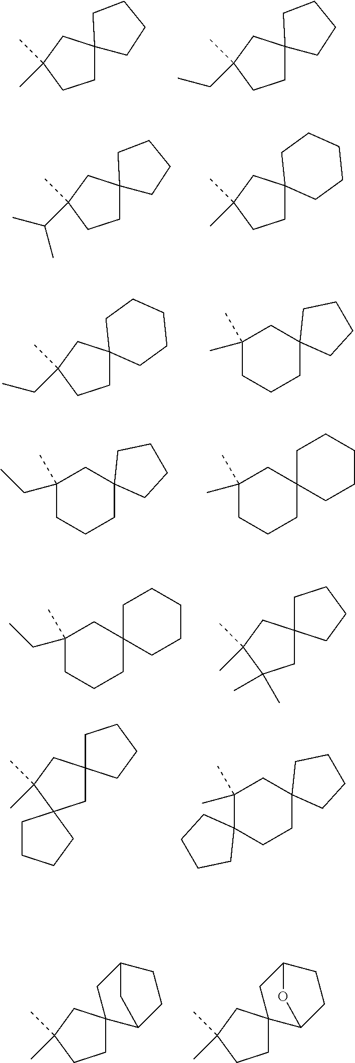

Illustrative, non-limiting examples of the acid labile group having formula (L9) are given below.

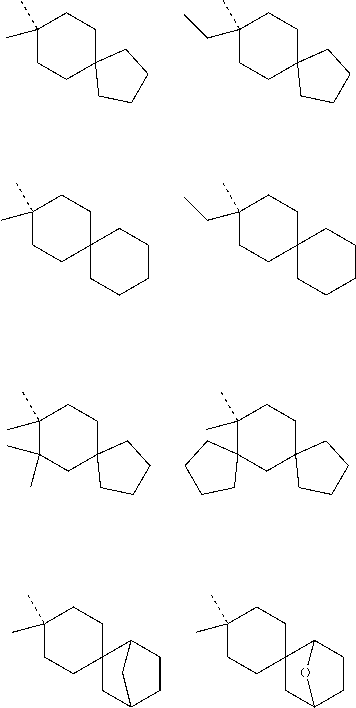

Examples of the monomer having formula (B-1) are shown below, but not limited thereto. Herein R^{A} is as defined above.

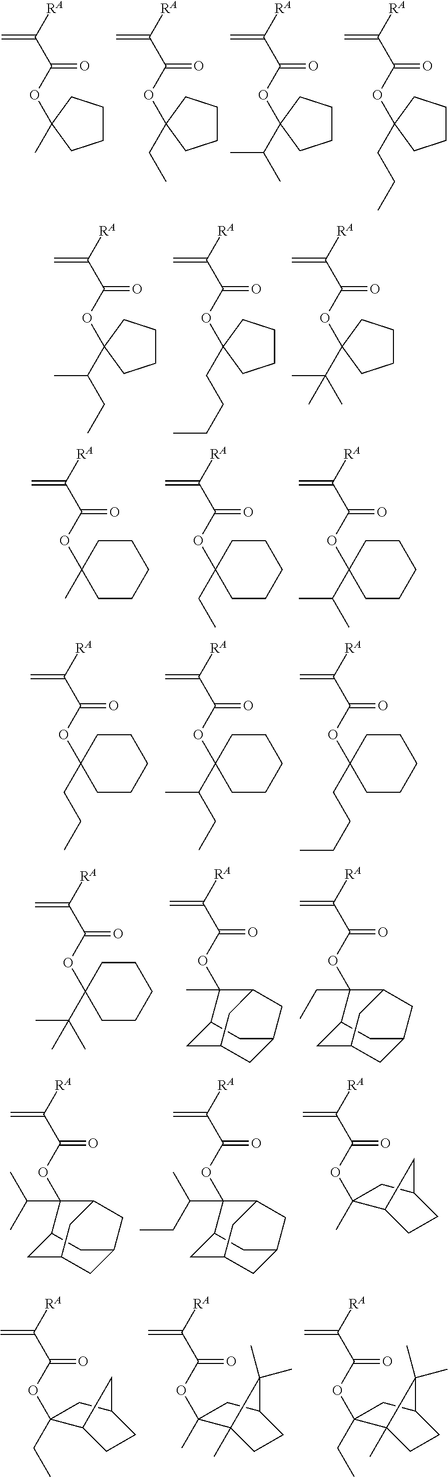

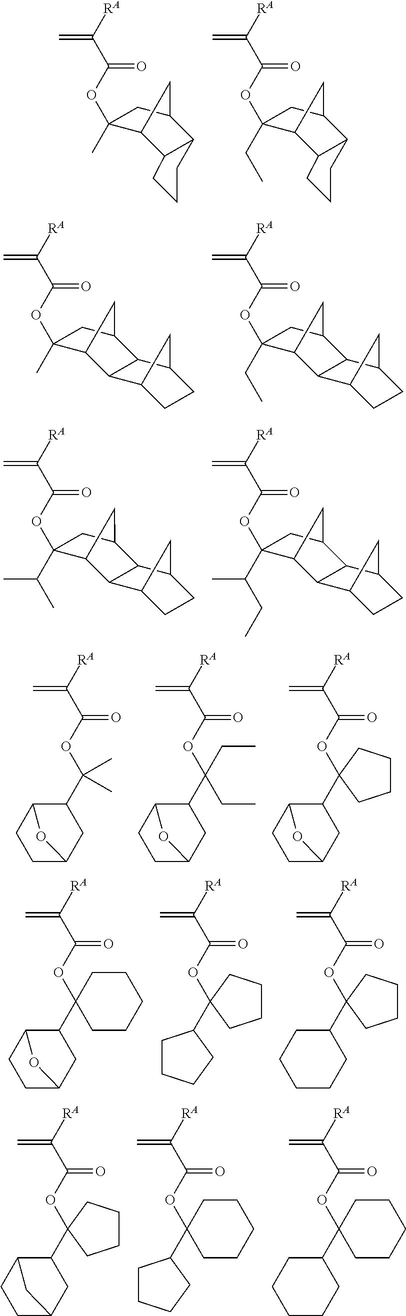

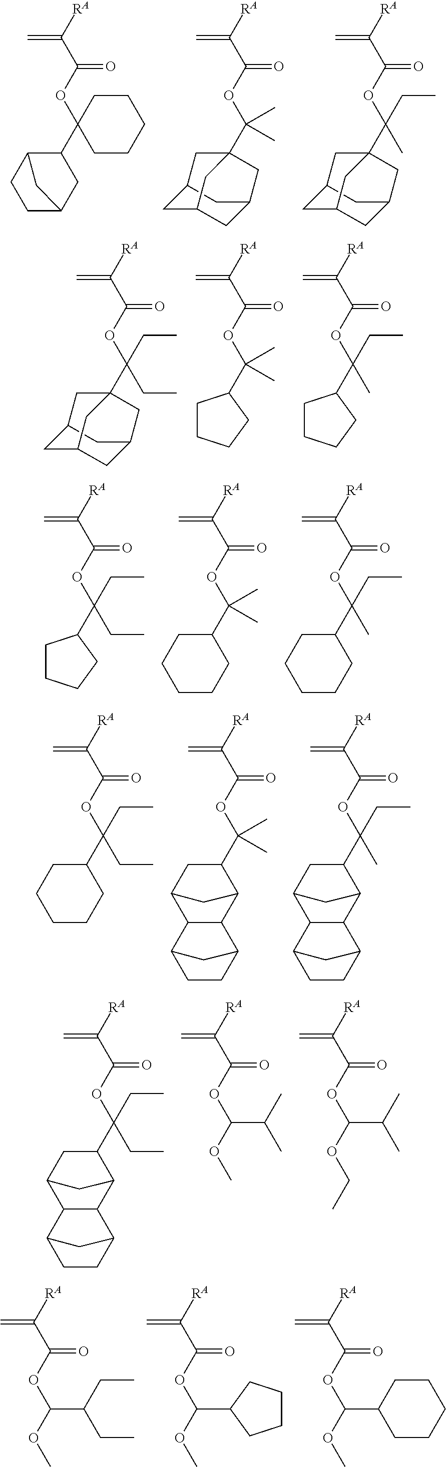

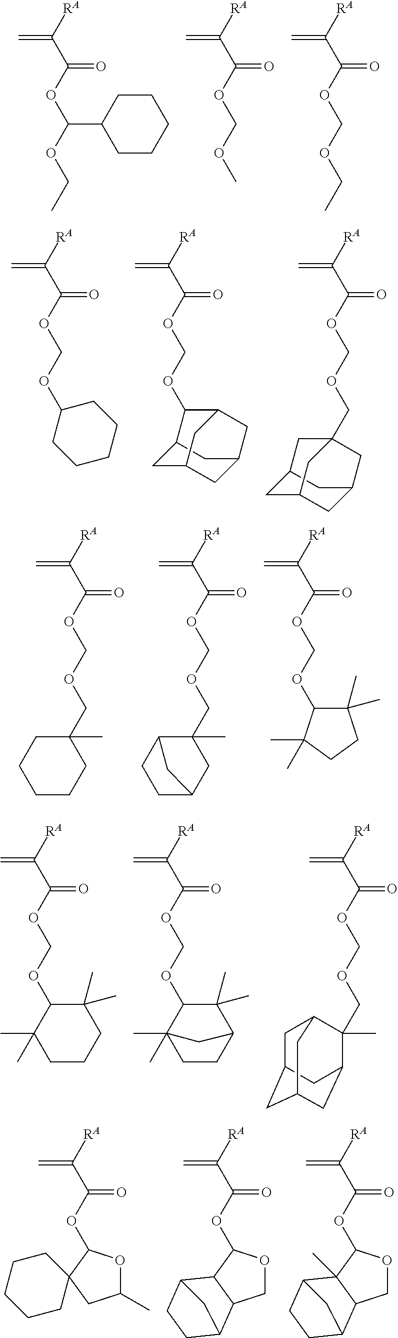

Examples of the monomer having formula (B-2) are shown below, but not limited thereto. Herein R^{A} is as defined above.

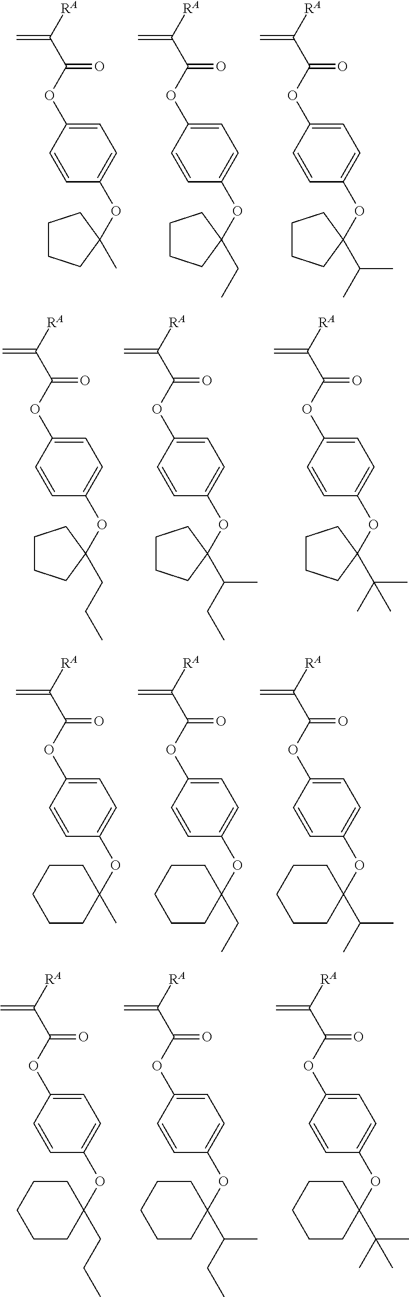

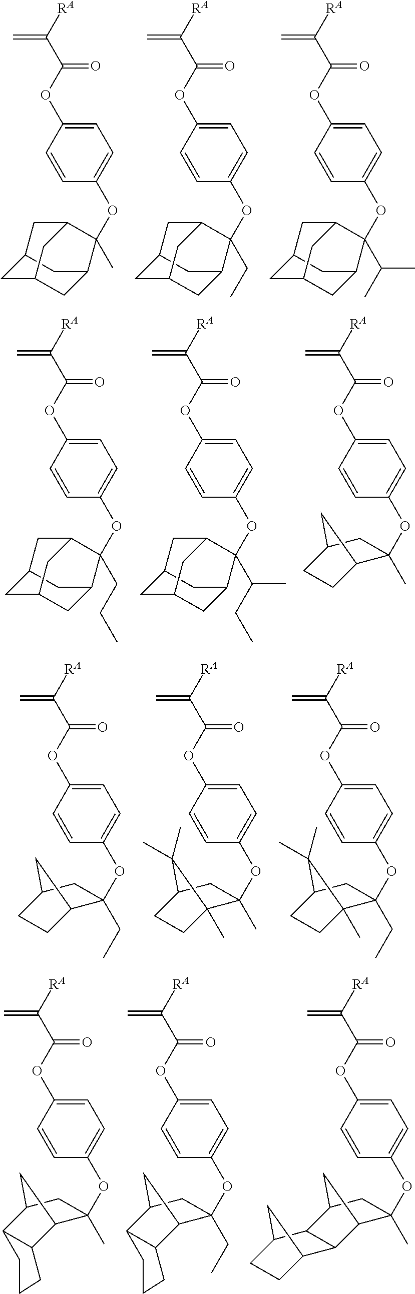

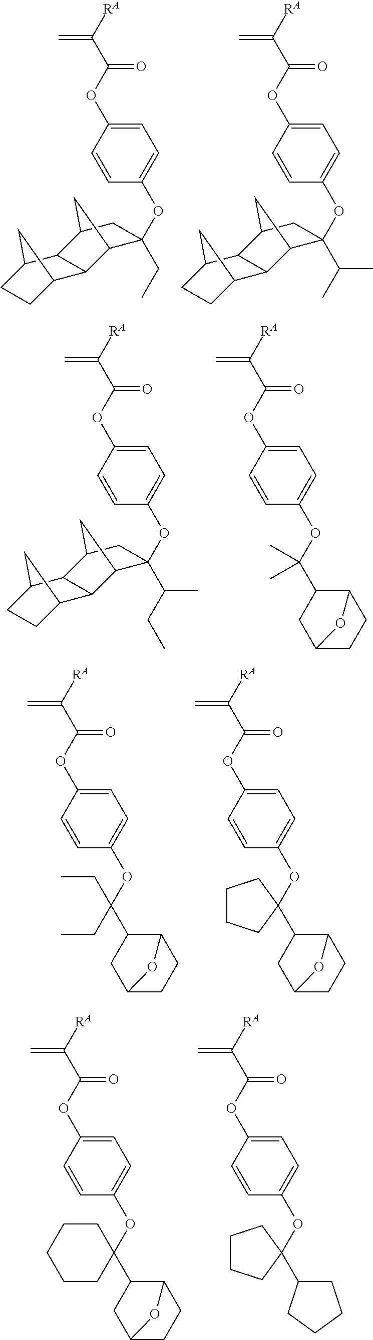

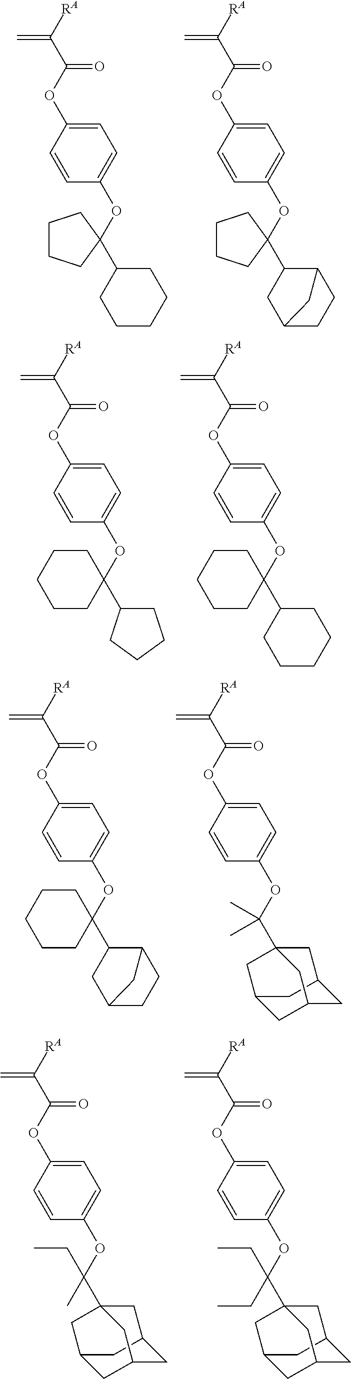

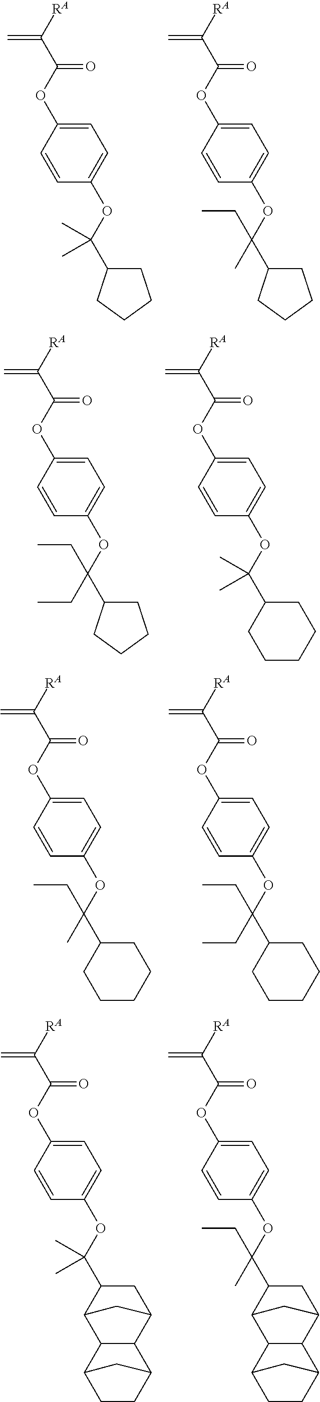

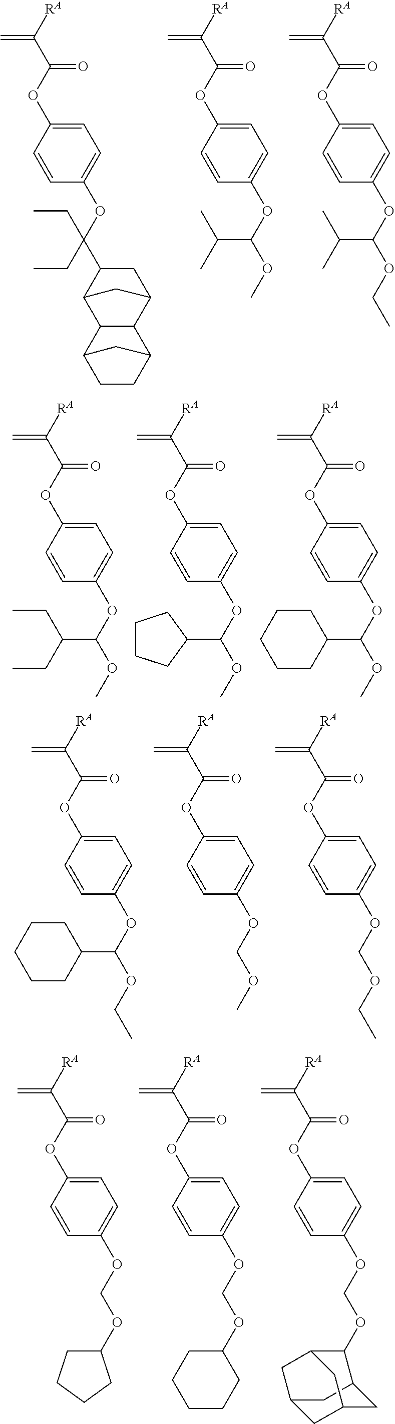

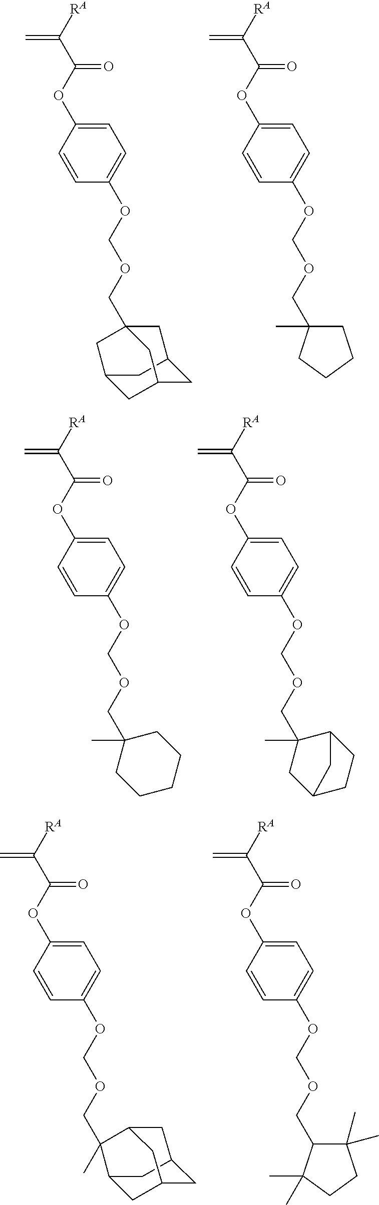

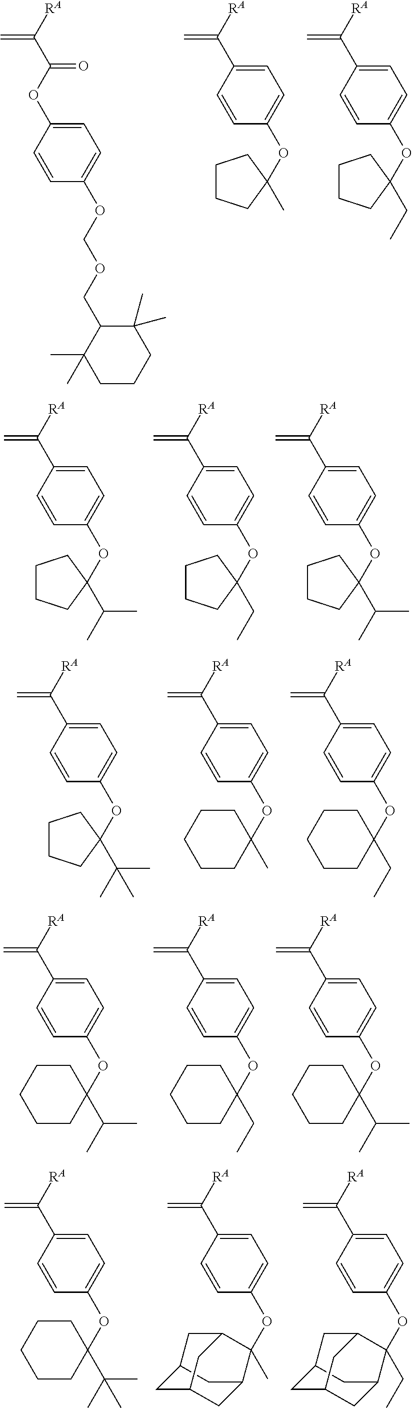

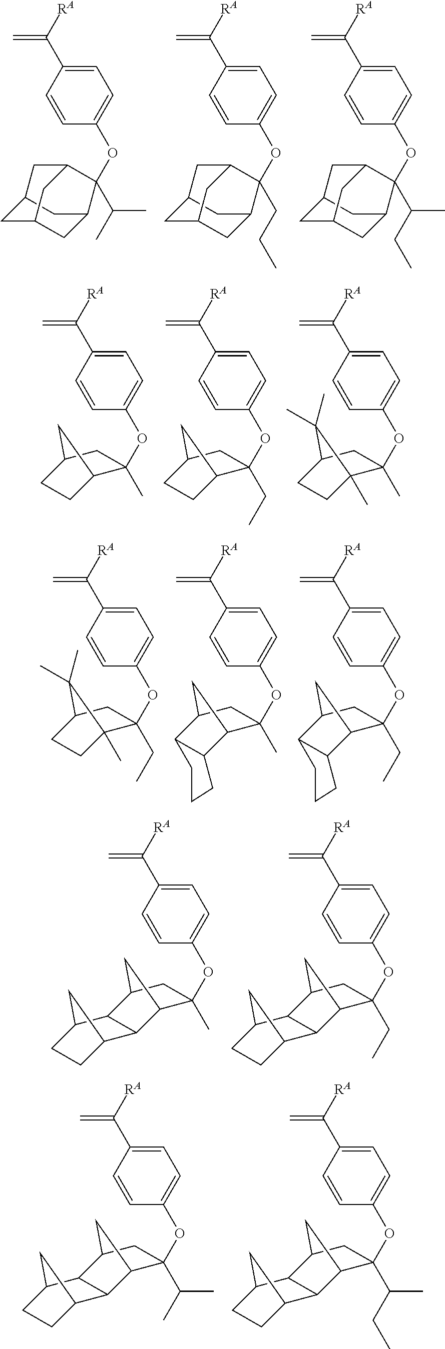

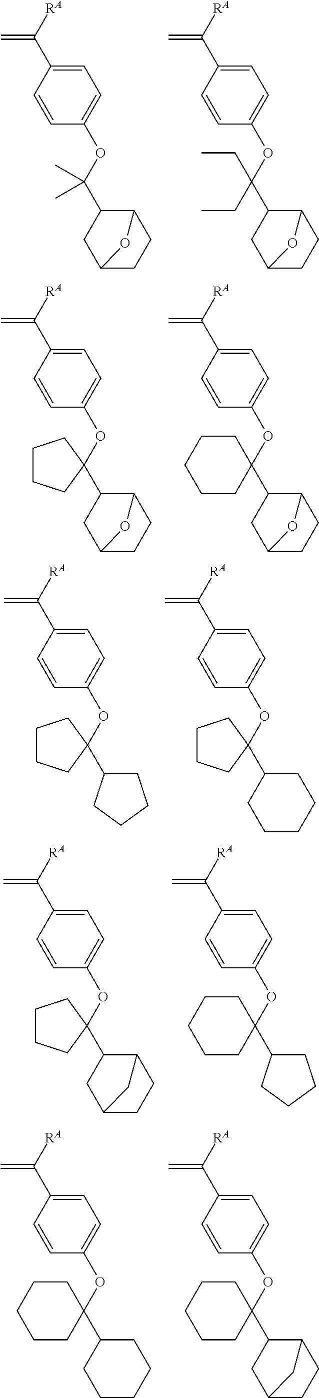

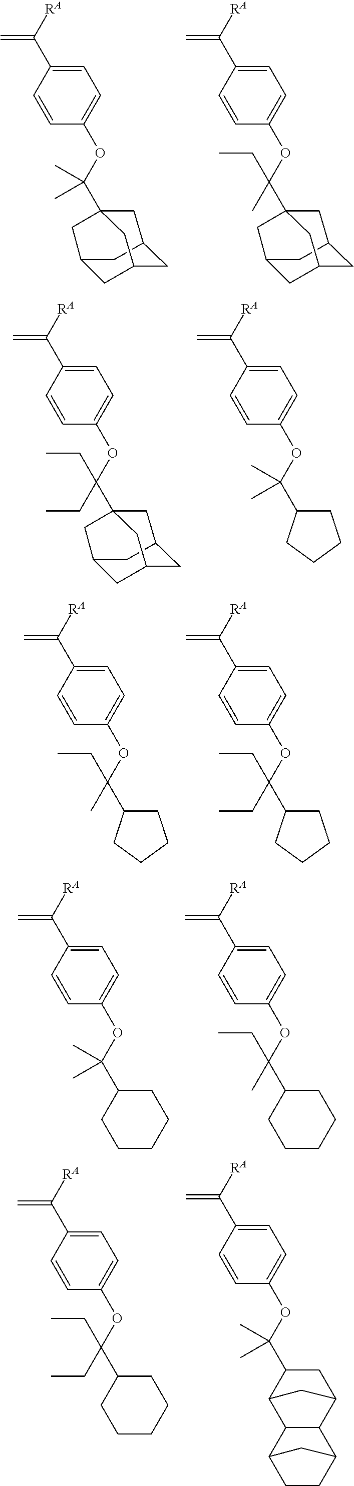

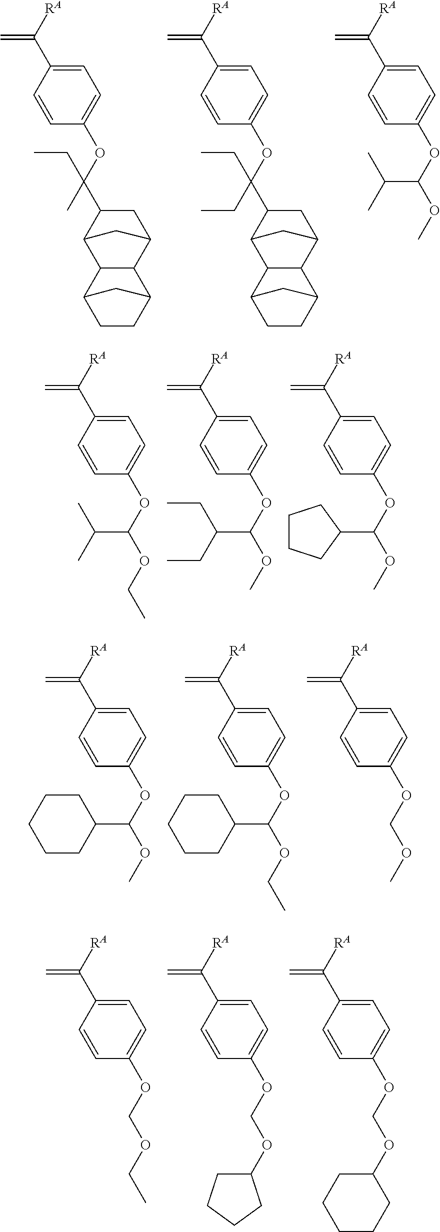

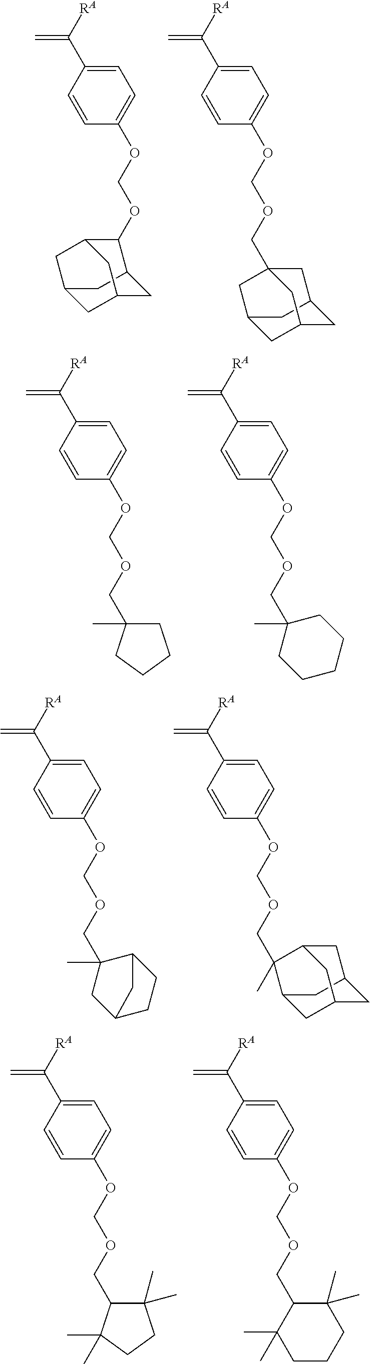

Of the acid labile groups represented by X^{A}, the C₄-C₂₀ tertiary alkyl group, trialkylsilyl group in which each alkyl moiety is of 1 to 6 carbon atoms, and C₄-C₂₀ oxoalkyl group are as exemplified above for R^{L04}.

### Monomer (C)

Examples of monomer (C) having a phenolic hydroxyl group include monomers having the formula (C-1).

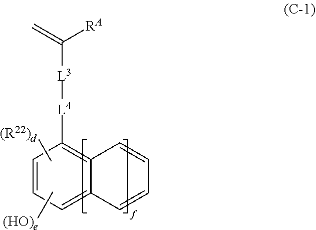

Herein R^{A} is as defined above. R²² is each independently hydrogen or a C₁-C₆ alkyl group which may contain an ether bond or carbonyl moiety. L³ is a single bond, carbonyloxy group or amide group. L⁴ is a single bond or C₁-C₇ alkanediyl group which may contain an ether bond or carbonyl moiety. The subscript d is an integer meeting d≤5+2f−e, e is an integer of 1 to 5, and f is an integer of 0 to 2.

In formula (C-1), examples of the C₁-C₆ alkyl group which may contain an ether bond or carbonyl moiety, represented by R²², include methyl, ethyl, propyl, isopropyl, n-butyl, sec-butyl, tert-butyl, pentyl, hexyl, heptyl, octyl, cyclopentyl, cyclohexyl, and the following groups, but are not limited thereto.

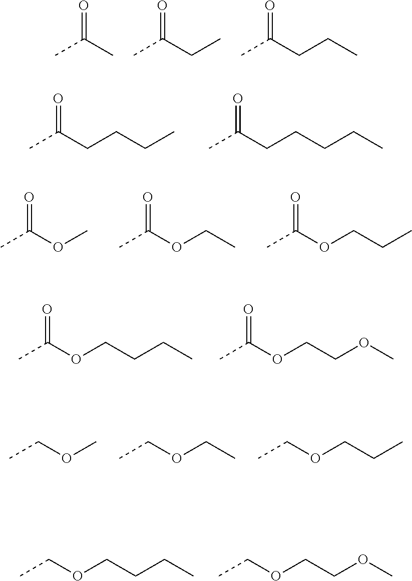

In formula (C-1), examples of the C₁-C₇ alkanediyl group which may contain an ether bond or carbonyl moiety, represented by L⁴, include methylene, ethylene, propane-1,3-diyl, butane-1,4-diyl, pentane-1,5-diyl, hexane-1,6-diyl, heptane-1,7-diyl, and the groups shown below, but are not limited thereto.

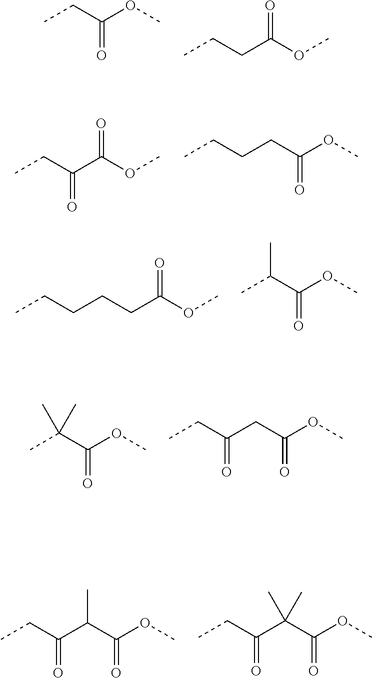

Examples of the monomer having formula (C-1) are shown below, but not limited thereto. Herein R^{A} is as defined above.

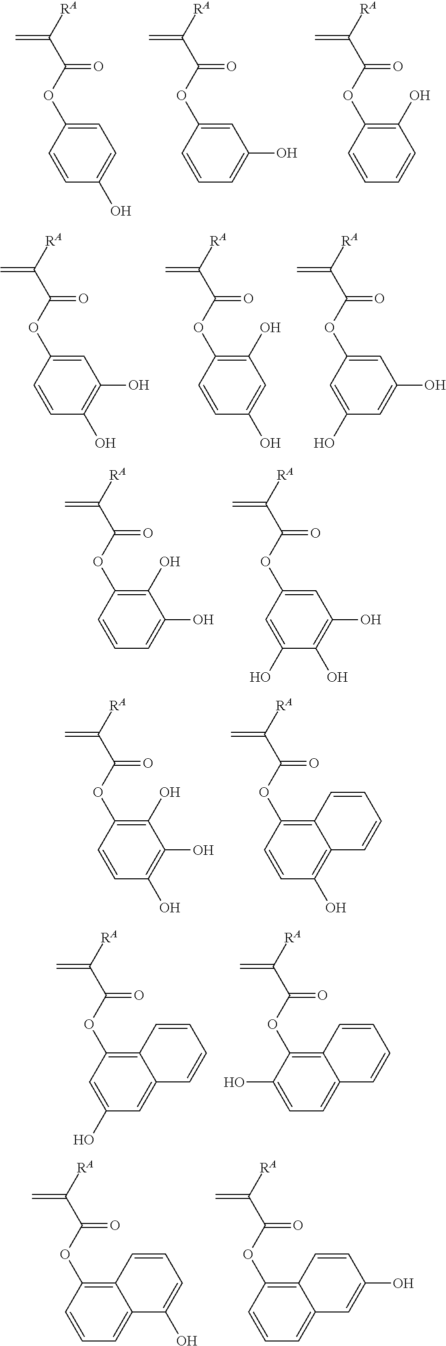

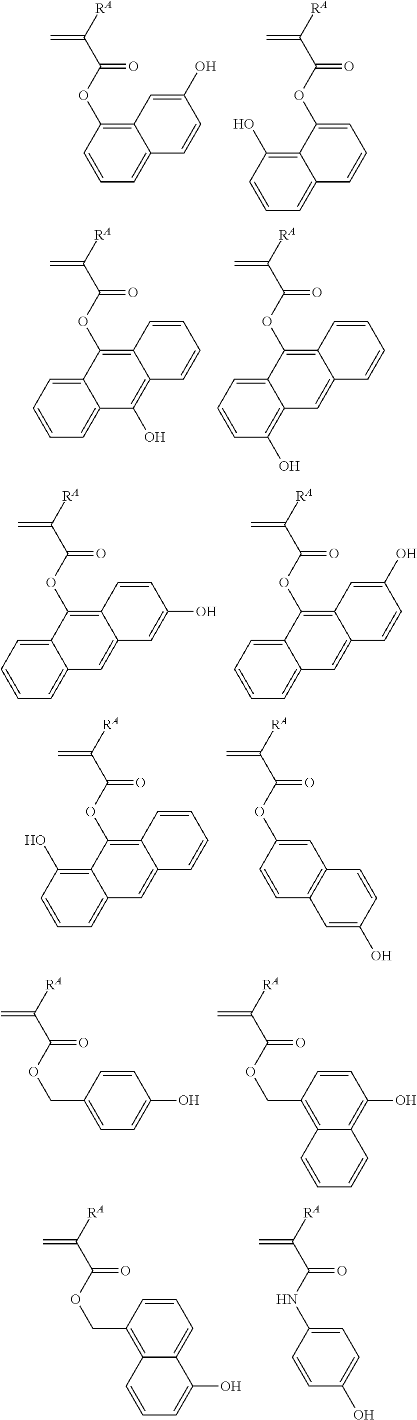

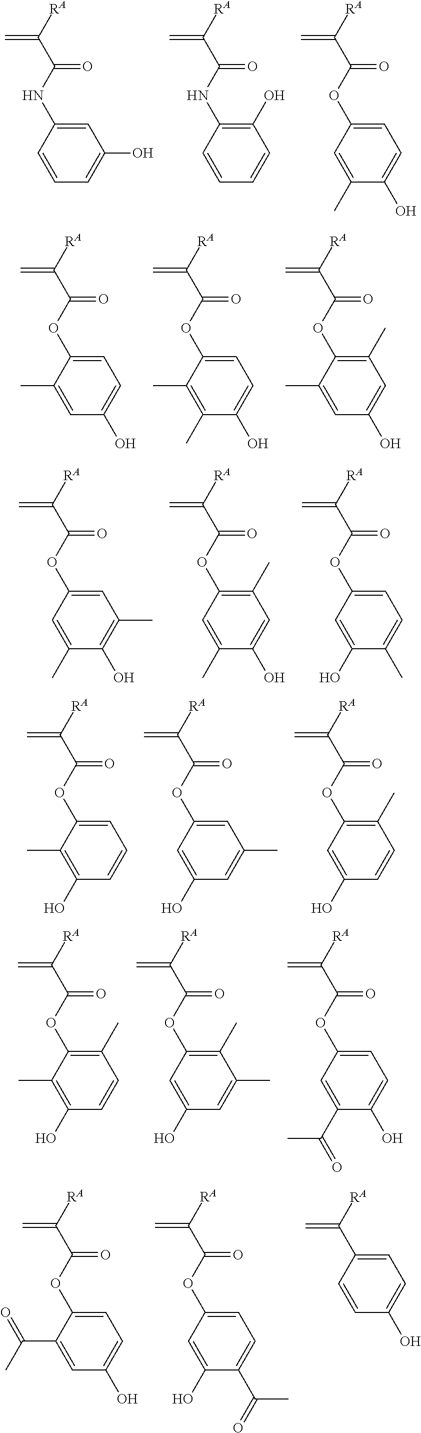

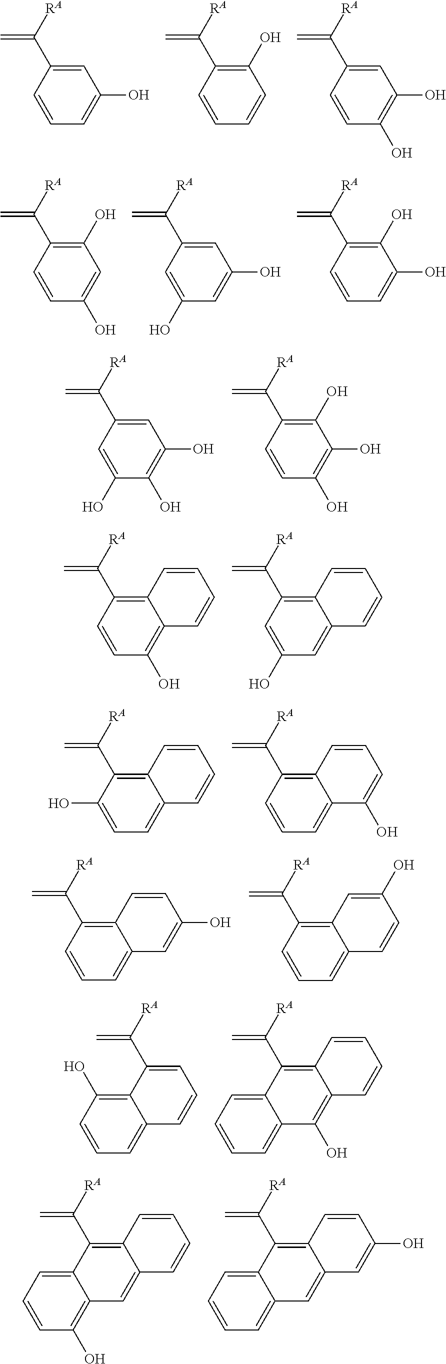

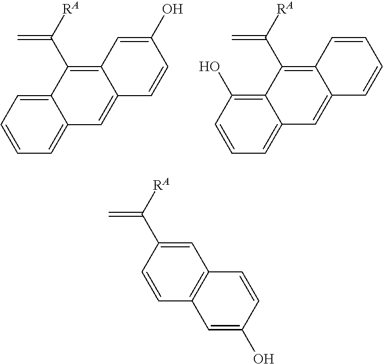

In addition to the recurring units derived from monomers (A) to (C), the polymer may further comprise recurring units derived from a monomer having the formula (D) (referred to as monomer (D)), a monomer having the formula (E) (referred to as monomer (E)), and/or a monomer having the formula (F) (referred to as monomer (F)), if necessary.

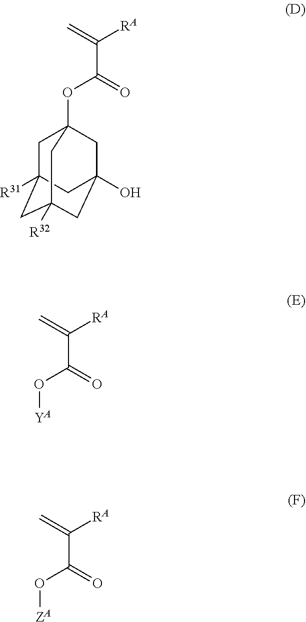

In formulae (D) to (F), R^{A} is as defined above. R³¹ and R³² are each independently hydrogen or hydroxyl. Y^{A} is a substituent group having a lactone or sultone structure. Z^{A} is hydrogen, a C₁-C₁₅ monovalent fluorinated hydrocarbon group or C₁-C₁₅ monovalent fluoroalcohol-containing group.

Examples of monomer (D) are shown below, but not limited thereto. Herein R^{A} is as defined above.

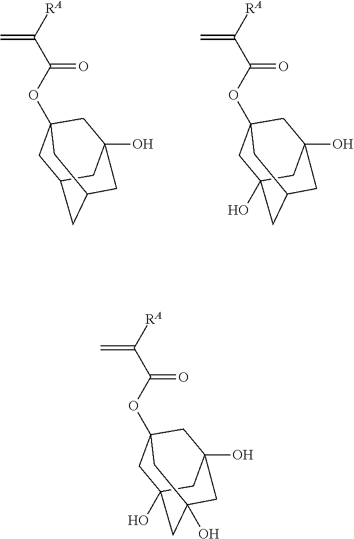

Examples of monomer (E) are shown below, but not limited thereto. Herein R^{A} is as defined above.

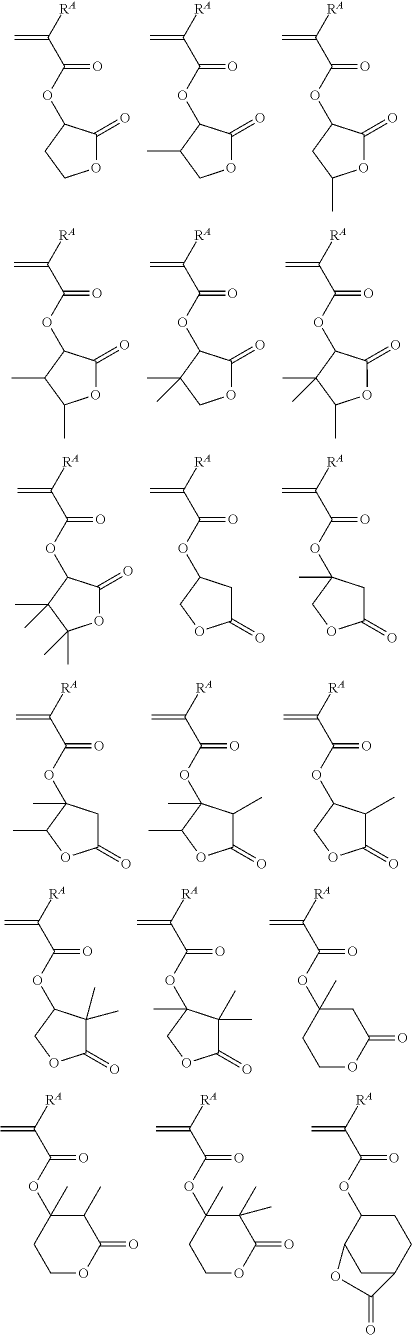

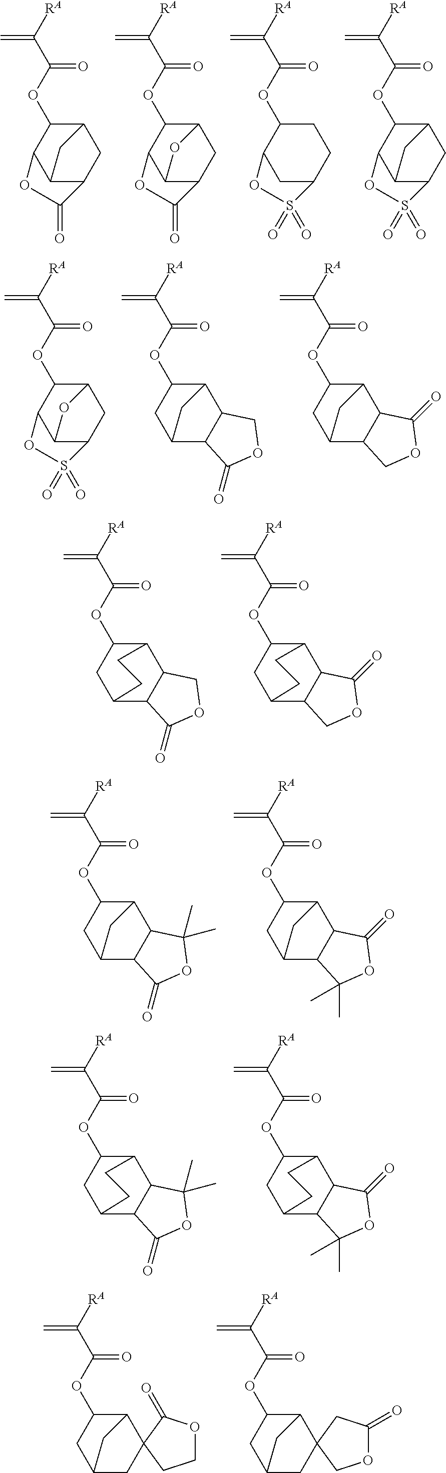

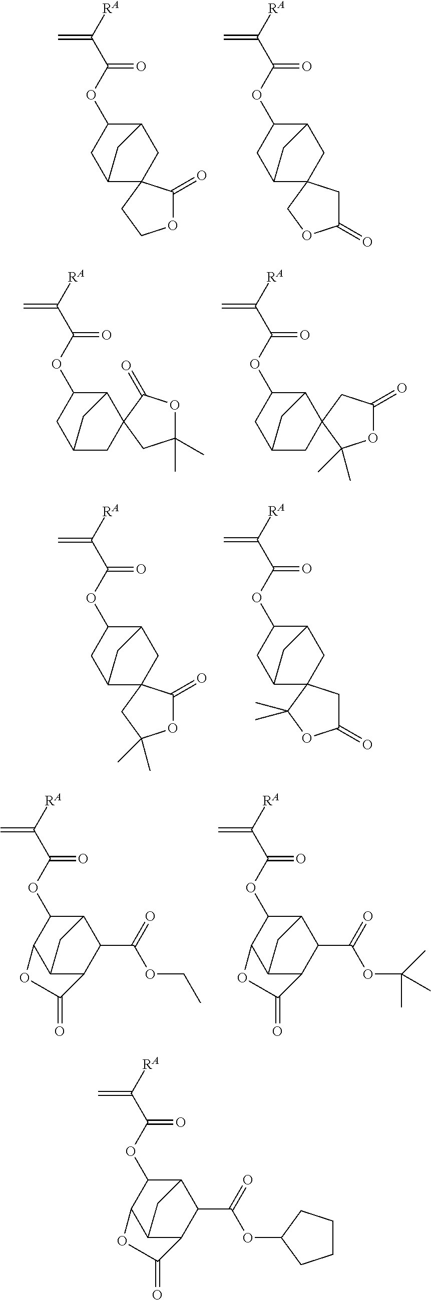

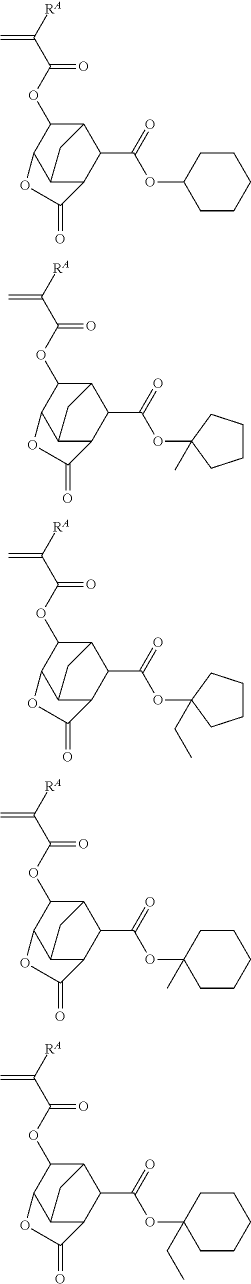

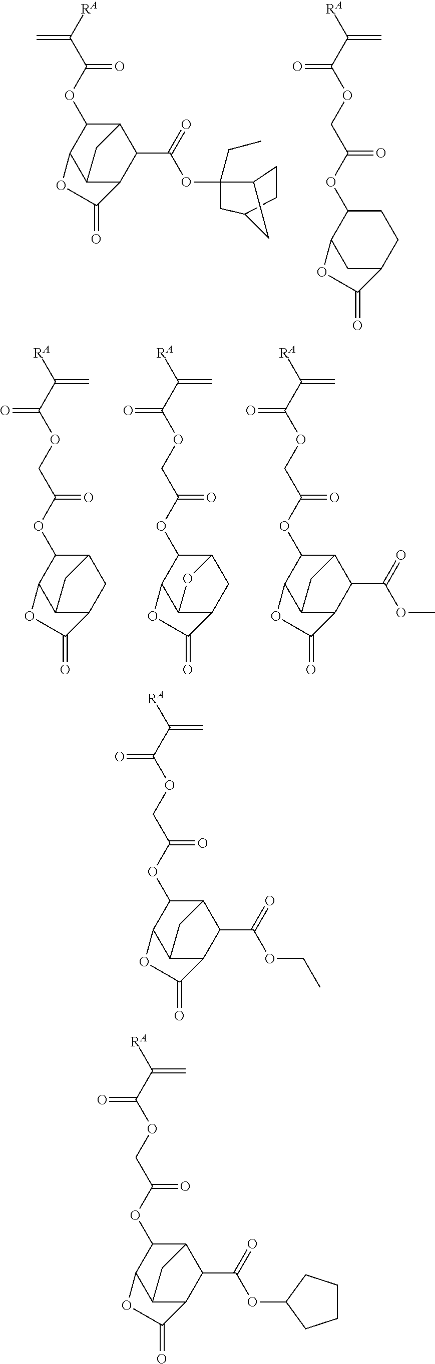

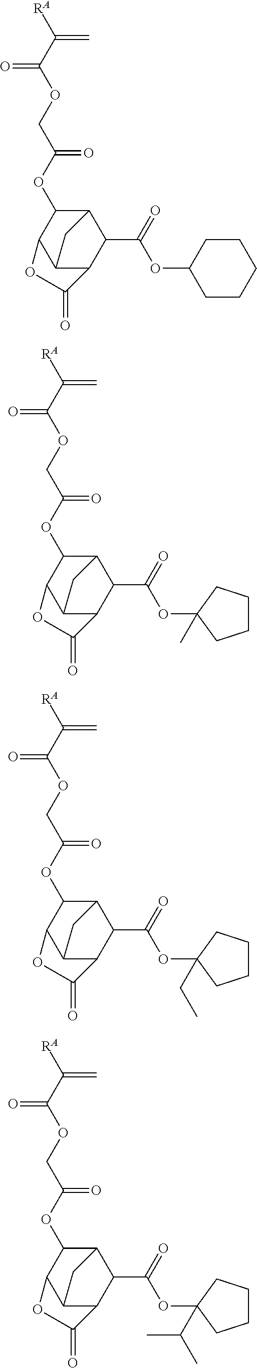

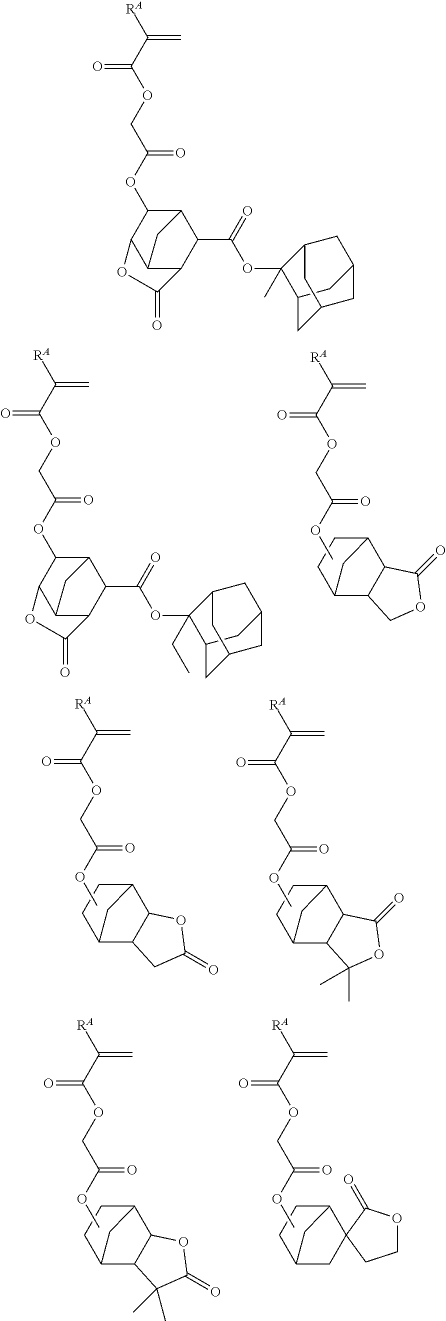

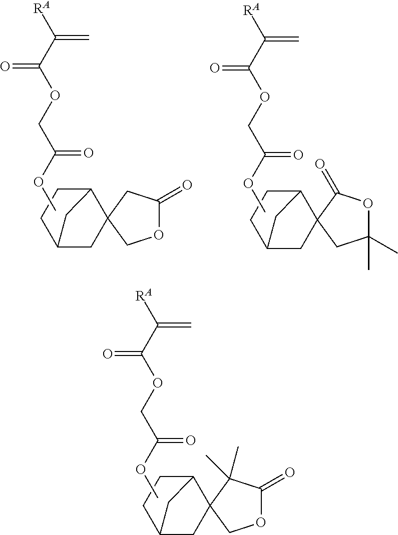

Examples of monomer (F) are shown below, but not limited thereto. Herein R^{A} is as defined above.

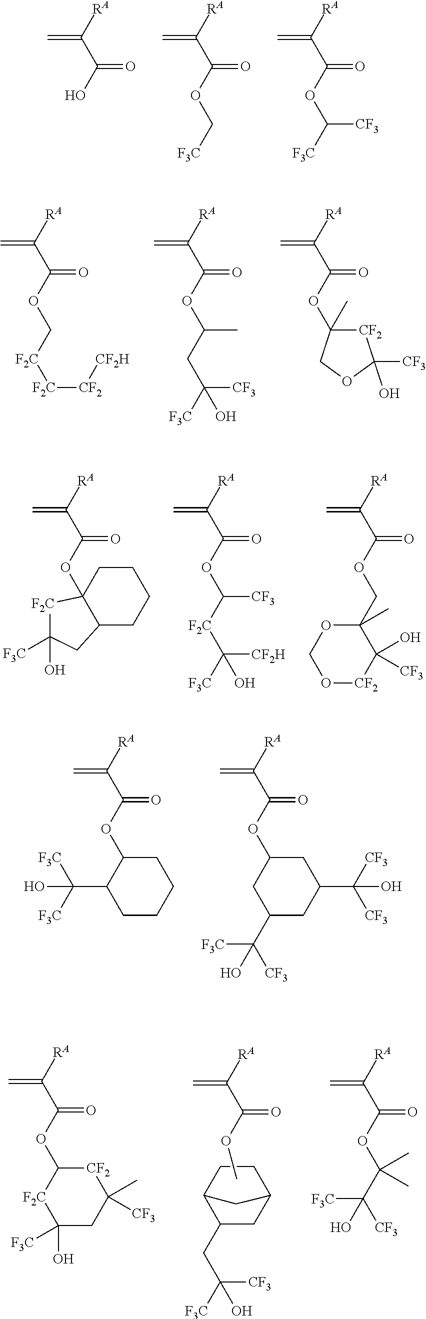

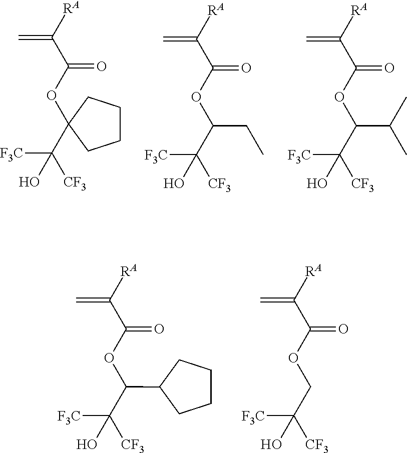

In addition to the foregoing units, the polymer may further comprise recurring units derived from other monomers having a carbon-carbon double bond, for example, substituted acrylic acid esters such as methyl methacrylate, methyl crotonate, dimethyl maleate and dimethyl itaconate, unsaturated carboxylic acids such as maleic acid, fumaric acid, and itaconic acid, cyclic olefins such as norbomene, norbomene derivatives, and tetracyclo[4.4.0.1^{2,5}.1^{7,10}]dodecene derivatives, unsaturated acid anhydrides such as itaconic anhydride, α-methylene-γ-butyrolactones, α-methylstyrenes, and the like.

In the polymer, the contents of the recurring units derived from the foregoing monomers are not particularly limited, but preferably fall in the following range (mol %):
(I) 1 to 50 mol %, more preferably 1 to 30 mol %, even more preferably 1 to 20 mol % of recurring units of one or more type derived from monomer (A),
(II) 1 to 98 mol %, more preferably 1 to 80 mol %, even more preferably 10 to 70 mol % of recurring units of one or more type derived from monomer (B),
(III) 1 to 98 mol %, more preferably 1 to 80 mol %, even more preferably 10 to 70 mol % of recurring units of one or more type derived from monomer (C), and
(IV) 0 to 97 mol %, more preferably 0 to 70 mol %, even more preferably 0 to 50 mol % of recurring units of one or more type derived from monomers other than monomers (A) to (C).

The polymer should preferably have a weight average molecular weight (Mw) in the range of 1,000 to 500,000, and more preferably 3,000 to 100,000, as measured by GPC versus polystyrene standards. The range of Mw ensures etching resistance, a high contrast before and after exposure, and satisfactory resolution.

If a polymer has a wide molecular weight distribution or dispersity (Mw/Mn), which indicates the presence of lower and higher molecular weight polymer fractions, there is a possibility that following exposure, foreign matter is left on the pattern or the pattern profile is exacerbated. The influences of Mw and Mw/Mn become stronger as the pattern rule becomes finer. Therefore, the polymer should preferably have a dispersity (Mw/Mn) of 1.0 to 3.0, especially 1.0 to 2.5, in order to provide a resist composition suitable for micropatteming to a small feature size.

The method of preparing the polymer defined above involves the steps of feeding a monomer solution containing monomer (A), monomer (B), and monomer (C) in a solvent (S) to a reactor and effecting polymerization reaction in the reactor.

When a polymer comprising recurring units derived from other monomer(s) as well as the recurring units derived from monomers (A) to (C) is prepared, it suffices to add monomers (D) to (F) and other monomers to the monomer solution.

The polymerization reaction may be carried out by dissolving the monomers in a solvent (S), adding a polymerization initiator to the monomer solution, and heating the solution. Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The initiator may be added in an amount of 0.01 to 25 mol % based on the total of monomers to be polymerized. The reaction temperature is preferably 50 to 150° C., more preferably 60 to 100° C. The reaction time is preferably 2 to 24 hours, a time of 2 to 12 hours being more preferred in view of production efficiency.

The polymerization initiator may be added to the monomer solution, which is fed to the reactor. Alternatively, a solution of the polymerization initiator is prepared separately from the monomer solution, and the monomer and initiator solutions be independently fed to the reactor. Since there is a possibility that the initiator generates a radical in the standby time, by which polymerization reaction takes place to form a ultrahigh molecular weight compound, it is preferred from the standpoint of quality control that the monomer solution and the initiator solution be independently prepared and added dropwise. The acid labile group that has been incorporated in the monomer may be kept as such, or the polymerization may be followed by protection or partial protection. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

In the practice of the invention, polymerization reaction is carried out under the condition that the monomer solution in the reactor has a monomer concentration of at least 35% by weight. The polymerization reaction under this condition ensures that the monomers are fully consumed within a sufficient reaction time not to compromise production efficiency and the contents of residual monomers after polymerization and after purification are minimized. If polymerization reaction is carried out at a monomer concentration of less than 35% by weight, the reaction time must be prolonged before a residual monomer content of equivalent level can be reached. This is disadvantageous from the aspect of production efficiency.

The amounts of monomers in the monomer solution may be set appropriate, for example, so as to meet the aforementioned preferred contents of recurring units.

The solvent (S) contains at least one compound selected from compounds having the following formulae (S-1) and (S-2).

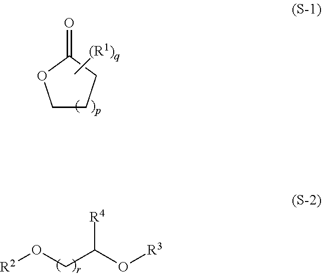

In formulae (S-1) and (S-2), R¹ is hydrogen, hydroxyl, or an optionally substituted C₁-C₈ alkyl group. R² to R⁴ are each independently hydrogen or an optionally substituted C₁-C₈ alkyl group. The subscript p is an integer of 1 to 3, q is an integer of 0 to 2, and r is an integer of 1 to 3.

The optionally substituted C₁-C₈ alkyl group may be straight, branched or cyclic and examples thereof include methyl, ethyl, propyl, isopropyl, n-butyl, sec-butyl, tert-butyl, pentyl, hexyl, heptyl, octyl, cyclopentyl, cyclohexyl, and substituted forms of the foregoing in which some hydrogen is substituted by hydroxyl or the like.

Examples of the solvent having formula (S-1) are given below, but not limited thereto.

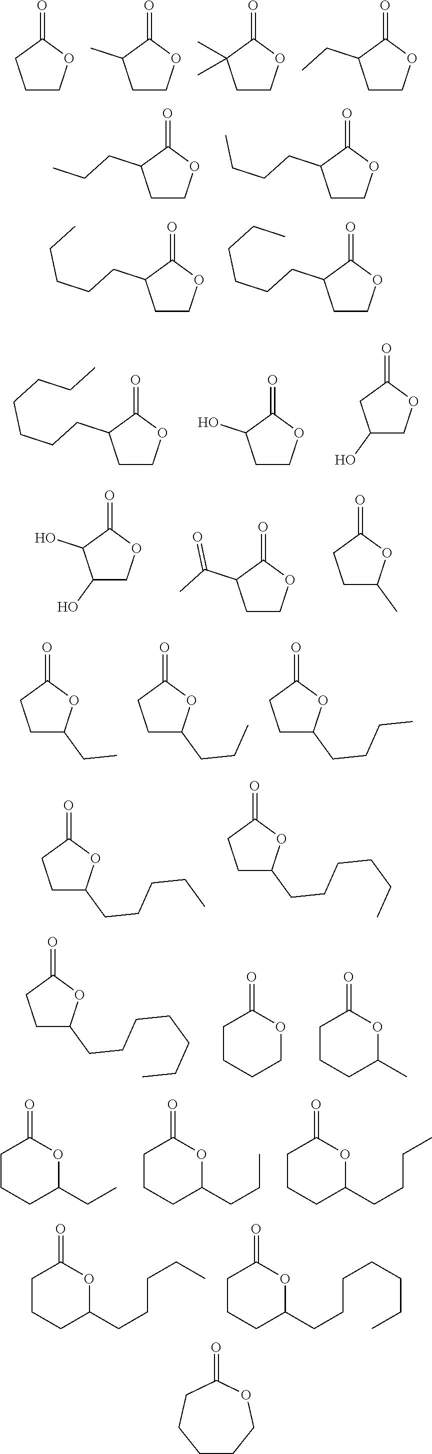

Examples of the solvent having formula (S-2) are given below, but not limited thereto.

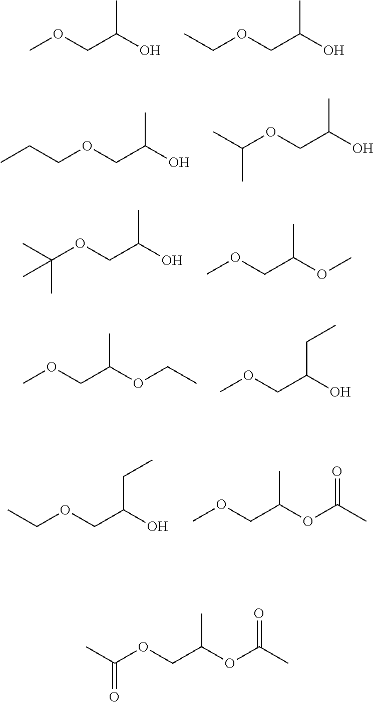

The solvent (S) is preferably used in an amount of 1 to 100% by weight, more preferably 10 to 100% by weight, even more preferably 20 to 100% by weight of the overall solvent used for polymerization. On use of solvent (S), monomer (A) may be dissolved in a high concentration, enabling to set the monomer concentration of the monomer solution higher than in the prior art. Particularly when the solvent having formula (S-1) is used, monomer (A) may be dissolved in a higher concentration. This enables to raise the conversion rate of monomers during polymerization reaction and to minimize any residual monomers after polymerization reaction.

Besides, an organic solvent other than the solvent (S) may be used during polymerization. Suitable organic solvents include toluene, benzene, tetrahydrofuran (THF), diethyl ether, dioxane, and methyl ethyl ketone (MEK). Such an organic solvent may be used along with the solvent (S). If necessary, the monomer solution may be bubbled with a nitrogen stream or kept in vacuum to remove dissolved oxygen out of the system.

If necessary, the polymerization reaction step may be followed by the purifying step of adding the reaction solution to a poor solvent for inducing re-precipitation. The poor solvent used herein may be selected as appropriate depending on the type of polymer. Typical poor solvents include, but are not limited to, hydrocarbons such as toluene, xylene, hexane and heptane, ethers such as diethyl ether, tetrahydrofuran, dibutyl ether, ketones such as acetone and 2-butanone, esters such as ethyl acetate and butyl acetate, and water. Such poor solvents may be used alone or in admixture.

The polymer preparing method of the invention is characterized in that the amount of monomer (A) remaining in the reaction solution at the end of reaction is up to 1.5% by weight, and the amount of monomer (A) remaining in the polymer as purified is up to 1.0% by weight. Reducing the amount of residual monomer enables defect suppression and quality stabilization. The amount of monomer (A) remaining in the polymer is preferably up to 0.7% by weight, more preferably up to 0.5% by weight. The amount of residual monomer may be quantitatively determined typically by high performance liquid chromatography.

The polymer resulting from the inventive method may take any form. For example, the reaction solution obtained from polymerization reaction may be used as the final product. Also a powder polymer obtained from the purifying step of adding the polymerization solution to a poor solvent for inducing re-precipitation may be handled as the final product. It is preferred from the standpoints of operation efficiency and consistent quality that a polymer solution obtained by dissolving the powder polymer from the purifying step in a solvent be handled as the final product. Examples of the solvent used herein include those described in JP-A 2008-111103, paragraphs [0144]-[0145] (U.S. Pat. No. 7,537,880), for example, ketones such as cyclohexanone and methyl-2-n-pentyl ketone; alcohols such as 3-methoxybutanol, 3-methyl-3-methoxybutanol, 1-methoxy-2-propanol, and 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as γ-butyrolactone (GBL); alcohols such as diacetone alcohol; and high-boiling alcohol solvents such as diethylene glycol, propylene glycol, glycerol, 1,4-butanediol and 1,3-butanediol, and mixtures thereof.

The polymer solution used as the final product preferably has a polymer concentration of 0.01 to 30% by weight, more preferably 0.1 to 20% by weight.

Preferably the reaction solution or the polymer solution may be filtrated through a filter. The filtration is advantageous for consistent quality because foreign particles or gel which can cause defects are removed.

Examples of the material of which the filter is made include fluorocarbon, cellulose, nylon, polyester, and hydrocarbon-based materials. In the step of filtrating resist compositions, filters made of materials based on fluorocarbons, typically Teflon®, hydrocarbons such as polyethylene and polypropylene, and nylon are preferred. The pore size of the filter may be selected as appropriate depending on the desired cleanness and is preferably up to 100 nm, more preferably up to 20 nm. The solution may be passed through a single filter or an assembly of plural filters. The solution may be filtered one pass, but preferably plural passes by circulating the solution. The filtration step may be performed in an arbitrary order or arbitrary times in the polymer preparing method. Preferably the reaction solution after polymerization reaction or the polymer solution or both are filtered.

### EXAMPLES

Examples of the invention are given below by way of illustration and not by way of limitation. All parts (pbw) and % are by weight unless otherwise stated. For all polymers, Mw is determined by GPC versus polystyrene standards using N,N-dimethylformamide solvent.

The monomer (A) (MA-1 to MA-3), monomer (B) (MB-1, MB-2), and monomer (C) (MC-1 to MC-3) used in Examples are shown below.

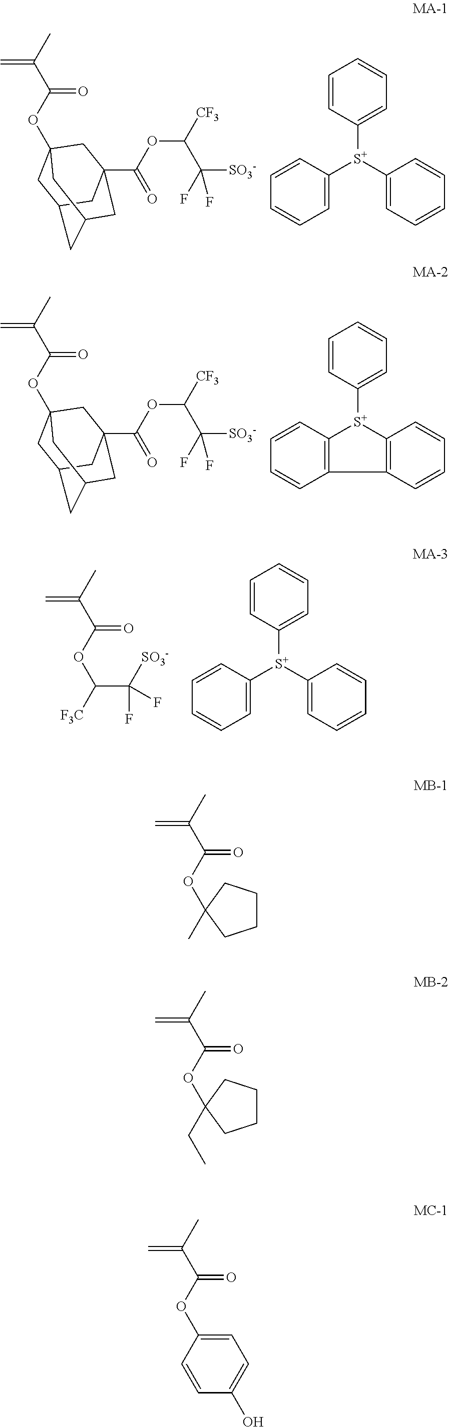

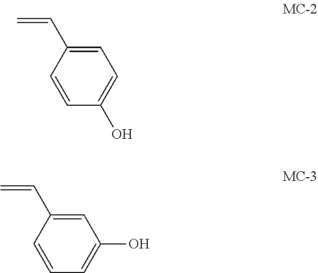

### [1] Preparation of Polymers

### Example 1-1

Preparation of Polymer P-1

In nitrogen atmosphere, a monomer solution was prepared by dissolving 21.5 g of MA-1, 16.3 g of MB-1, 12.1 g of MC-1, and 4.47 g of dimethyl 2,2′-azobisisobutyrate in 69.6 g of GBL. In nitrogen atmosphere and with stirring, the solution was added dropwise to 23.2 g of GBL at 80° C. over 4 hours. After the dropwise addition, the polymerization solution was stirred at 80° C. for 4 hours. The solution was cooled to room temperature and added dropwise to 1,000 g of ultrapure water for precipitation. The solid precipitate was filtered and vacuum dried at 50° C. for 20 hours, obtaining Polymer P-1 in white solid form. The amount was 45 g, and the yield was 90%. Polymer P-1 had a Mw of 11,500 and a Mw/Mn of 2.10. The amount of residual MA-1 in the reaction solution at the end of polymerization reaction was 0.90 wt %. The amount of residual MA-1 in the polymer after re-precipitation was 0.30 wt %.

### Examples 1-2 to 1-12 and Comparative Examples 1-1 to 1-5

Preparation of Polymers P-2 to P-12 and Comparative Polymers PC-1 to PC-5

Polymers P-2 to P-12 and Comparative Polymers PC-1 to PC-5 were prepared by the same procedure as in Example 1-1 except that the type and amount (or blend ratio) of monomers and the polymerization solvent were changed.

TABLE 1

| | | | | | | | | | Amount | |
|---|---|---|---|---|---|---|---|---|---|---|
| | | | | | | | | | of residual | |
| | | | | | | | | | monomer | Amount |
| | | | | | | | | | (A) in | of residual |
| | | | | | | Monomer | | | polymer- | monomer |
| | | Monomer | Monomer | Monomer | | concen- | | | rization | (A) |
| | | (A) | (B) | (C) | Polymerization | tration | | | solution | in polymer |
| | Polymer | (molar ratio) | (molar ratio) | (molar ratio) | solvent | (wt%) | Mw | Mw/Mn | (wt%) | (wt%) |
| Example | | | | | | | | | | |
| 1-1 | P-1 | MA-1 | MB-1 | MC-1 | GBL | 35 | 11,500 | 2.10 | 0.90 | 0.30 |
| | | (15) | (50) | (35) | | | | | | |
| 1-2 | P-2 | MA-2 | MB-1 | MC-1 | MEK/PGME | 35 | 12,000 | 2.00 | 0.90 | 0.40 |
| | | (15) | (50) | (35) | (1/1 in weight ratio) | | | | | |
| 1-3 | P-3 | MA-3 | MB-1 | MC-1 | MEK/GBL | 35 | 11,000 | 1.90 | 0.80 | 0.40 |
| | | (15) | (50) | (35) | (1/1 in weight ratio) | | | | | |
| 1-4 | P-4 | MA-1 | MB-1 | MC-2 | PGME | 35 | 10,000 | 2.00 | 0.70 | 0.30 |
| | | (15) | (50) | (35) | | | | | | |
| 1-5 | P-5 | MA-1 | MB-1 | MC-3 | PGME | 40 | 10,200 | 2.10 | 0.80 | 0.40 |
| | | (15) | (50) | (35) | | | | | | |
| 1-6 | P-6 | MA-2 | MB-1 | MC-2 | GBL/PGME | 35 | 10,000 | 1.90 | 0.70 | 0.40 |
| | | (15) | (50) | (35) | (1/1 in weight ratio) | | | | | |
| 1-7 | P-7 | MA-2 | MB-1 | MC-3 | GBL/PGME | 35 | 10,400 | 2.00 | 0.90 | 0.40 |
| | | (15) | (50) | (35) | (1/1 in weight ratio) | | | | | |
| 1-8 | P-8 | MA-3 | MB-1 | MC-2 | GBL/PGME | 35 | 8,800 | 1.80 | 0.80 | 0.60 |
| | | (15) | (50) | (35) | (2/1 in weight ratio) | | | | | |
| 1-9 | P-9 | MA-3 | MB-1 | MC-3 | GBL/PGME | 35 | 9,600 | 1.90 | 0.70 | 0.50 |
| | | (15) | (50) | (35) | (2/1 in weight ratio) | | | | | |
| 1-10 | P-10 | MA-1 | MB-2 | MC-1 | GBL | 40 | 9,000 | 1.90 | 0.60 | 0.30 |
| | | (15) | (50) | (35) | | | | | | |
| 1-11 | P-11 | MA-1 | MB-2 | MC-1 | GBL | 40 | 11,500 | 2.00 | 0.80 | 0.20 |
| | | (15) | (50) | (35) | | | | | | |
| 1-12 | P-12 | MA-1 | MB-2 | MC-1 | GBL | 35 | 13,000 | 2.20 | 3.00 | 0.30 |
| | | (20) | (50) | (30) | | | | | | |
| Comparative | | | | | | | | | | |
| Example | | | | | | | | | | |
| 1-1 | PC-1 | MA-1 | MB-1 | MC-1 | MEK | 35 | 11,500 | 2.20 | 2.60 | 2.70 |
| | | (15) | (50) | (35) | | | | | | |
| 1-2 | PC-2 | MA-2 | MB-1 | MC-1 | MEK/PGME | 30 | 11,000 | 2.10 | 2.60 | 2.30 |
| | | (15) | (50) | (35) | (1/1 in weight ratio) | | | | | |
| 1-3 | PC-3 | MA-3 | MB-1 | MC-1 | MEK/GBL | 30 | 9,000 | 1.90 | 2.50 | 2.40 |
| | | (15) | (50) | (35) | (1/1 in weight ratio) | | | | | |
| 1-4 | PC-4 | MA-1 | MB-1 | MC-2 | THF | 30 | 9,500 | 2.10 | 2.80 | 2.50 |
| | | (15) | (50) | (35) | | | | | | |
| 1-5 | PC-5 | MA-1 | MB-1 | MC-3 | MEK | 35 | 10,400 | 2.00 | 2.70 | 2.50 |
| | | (15) | (50) | (35) | | | | | | |

### [2] Preparation of Resist Composition

### Examples 2-1 to 2-12 and Comparative Examples 2-1 to 2-5

Resist compositions (R-1 to R-12) and comparative resist compositions (RC-1 to RC-5) in solution form were prepared by using the polymer (P-1 to P-12) or comparative polymer (PC-1 to PC-5) as the base resin, adding an acid generator, quencher, fluoropolymer, and solvent in accordance with the formulation shown in Table 2, mixing them for dissolution, and filtering through a Teflon® filter with a pore size of 0.2 μm. All the solvents contained 0.01 wt % of surfactant KH-20 (AGC).

TABLE 2

| | Resist | Base resin | Acid generator | Quencher | Fluoropolymer | Solvent 1 | Solvent 2 |
|---|---|---|---|---|---|---|---|
| | composition | (pbw) | (pbw) | (pbw) | (pbw) | (pbw) | (pbw) |
| Example | | | | | | | |
| 2-1 | R-1 | P-1 | — | Q-1 | F-1 | PGMEA | GBL |
| | | (100) | | (6) | (3) | (2,000) | (400) |
| 2-2 | R-2 | P-2 | — | Q-1 | F-1 | PGMEA | GBL |
| | | (100) | | (6) | (3) | (2,000) | (400) |
| 2-3 | R-3 | P-3 | — | Q-1 | F-1 | PGMEA | PGMEA |
| | | (100) | | (6) | (3) | (2,000) | (400) |
| 2-4 | R-4 | P-4 | PAG 1 | Q-1 | F-1 | PGMEA | PGMEA |
| | | (100) | (3) | (6) | (3) | (2,000) | (400) |
| 2-5 | R-5 | P-5 | — | Q-1 | F-1 | PGMEA | PGMEA |
| | | (100) | | (6) | (3) | (2,000) | (400) |
| 2-6 | R-6 | P-6 | — | Q-1 | F-1 | PGMEA | GBL |
| | | (100) | | (6) | (3) | (2,000) | (400) |
| 2-7 | R-7 | P-7 | — | Q-1 | F-1 | PGMEA | GBL |
| | | (100) | | (6) | (3) | (2,000) | (400) |
| 2-8 | R-8 | P-8 | — | Q-1 | F-1 | PGMEA | GBL |
| | | (100) | | (6) | (3) | (2,000) | (400) |
| 2-9 | R-9 | P-9 | — | Q-1 | F-1 | PGMEA | PGMEA |
| | | (100) | | (6) | (3) | (2,000) | (400) |
| 2-10 | R-10 | P-10 | — | Q-1 | F-1 | PGMEA | GBL |
| | | (100) | | (6) | (3) | (2,000) | (400) |
| 2-11 | R-11 | P-11 | — | Q-1 | F-1 | PGMEA | GBL |
| | | (100) | | (6) | (3) | (2,000) | (400) |
| 2-12 | R-12 | P-12 | — | Q-1 | F-1 | PGMEA | GBL |
| | | (100) | | (6) | (3) | (2,000) | (400) |
| Comparative | | | | | | | |
| Example | | | | | | | |
| 2-1 | RC-1 | P-1 | — | Q-1 | F-1 | PGMEA | GBL |
| | | (100) | | (6) | (3) | (2,000) | (400) |
| 2-2 | RC-2 | P-2 | — | Q-1 | F-1 | PGMEA | GBL |
| | | (100) | | (6) | (3) | (2,000) | (400) |
| 2-3 | RC-3 | P-3 | — | Q-1 | F-1 | PGMEA | PGMEA |
| | | (100) | | (6) | (3) | (2,000) | (400) |
| 2-4 | RC-4 | P-4 | PAG 1 | Q-1 | F-1 | PGMEA | GBL |
| | | (100) | (3) | (6) | (3) | (2,000) | (400) |
| 2-5 | RC-5 | P-5 | — | Q-1 | F-1 | PGMEA | PGMEA |
| | | (100) | | (6) | (3) | (2,000) | (400) |

The acid generator, quencher and fluoropolymer in Table 2 are identified below.

### Acid Generator: PAG-1

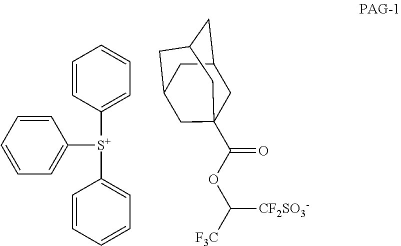

### Quencher: Q-1

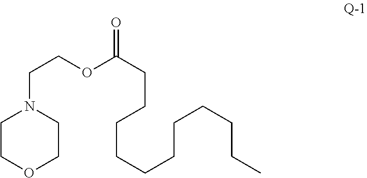 [SMILES: CCCCCCCCCCCC(=O)OCCN1CCOCC1]

### Fluoropolymer: F-1

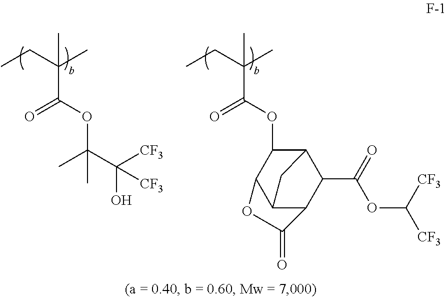

### [3] EUV Lithography Test

There was furnished a silicon substrate on which a silicon-containing spin-on hard mask (SHB-A940, Shin-Etsu Chemical Co., Ltd.) having a silicon content of 43 wt % had been deposited to a thickness of 20 nm. Each of resist compositions (R-1 to R-12, RC-1 to RC-5) was spin coated onto the silicon substrate and prebaked on a hotplate at 105° C. for 60 seconds to form a resist film of 30 nm thick. Using an EUV scanner NXE3300 (ASML, NA 0.33, dipole illumination), the resist film was exposed to EUV. The resist film was baked (PEB) at the temperature shown in Table 3 for 60 seconds and developed in a 2.38 wt % tetramethylammonium hydroxide aqueous solution for 30 seconds to form a 1:1 line-and-space pattern having a size of 16 nm.

The exposure dose (mJ/cm²) that provides a 16-nm 1:1 L/S pattern is reported as sensitivity. The LWR of the L/S pattern was measured under CD-SEM (CG-5000, Hitachi High-Technologies Corp.). The test results are shown in Table 3.

TABLE 3

| | | Resist | PEB | Sensitivity | LWR |
|---|---|---|---|---|---|
| | | composition | (° C.) | (mJ/cm²) | (nm) |
| Example | 3-1 | R-1 | 90 | 35.8 | 3.5 |
| | 3-2 | R-2 | 95 | 34.7 | 3.8 |
| | 3-3 | R-3 | 95 | 34.1 | 3.7 |
| | 3-4 | R-4 | 90 | 33.0 | 3.6 |
| | 3-5 | R-5 | 85 | 34.5 | 3.7 |
| | 3-6 | R-6 | 80 | 33.2 | 3.7 |
| | 3-7 | R-7 | 80 | 33.8 | 3.5 |
| | 3-8 | R-8 | 85 | 34.4 | 3.6 |
| | 3-9 | R-9 | 85 | 34.1 | 3.8 |
| | 3-10 | R-10 | 95 | 35.1 | 3.7 |
| | 3-11 | R-11 | 90 | 34.6 | 3.8 |
| | 3-12 | R-12 | 90 | 34.8 | 3.7 |
| Comparative | 3-1 | RC-1 | 90 | 35.6 | 4.2 |
| Example | 3-2 | RC-2 | 95 | 34.6 | 4.6 |
| | 3-3 | RC-3 | 95 | 34.0 | 4.5 |
| | 3-4 | RC-4 | 90 | 33.0 | 4.4 |
| | 3-5 | RC-5 | 85 | 34.4 | 4.3 |

As seen from the results in Table 3, resist compositions comprising the polymers prepared by the inventive method are superior in LWR to the polymers prepared by the well-known method.

Japanese Patent Application No. 2018-207176 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A method for preparing a polymer comprising recurring units derived from a monomer (A) adapted to be decomposed to generate an acid upon light exposure, recurring units derived from a monomer (B) having an acid labile group, and recurring units derived from a monomer (C) having a phenolic hydroxyl group, an amount of residual monomer (A) in the polymer being up to 1.0% by weight,
said method comprising the steps of feeding a monomer solution containing monomer (A), monomer (B), and monomer (C) in a solvent (S) to a reactor and effecting polymerization reaction in the reactor,
the monomer solution in the reactor having a monomer concentration of at least 35% by weight, and the solvent (S) containing at least one compound selected from compounds having the following formulae (S-1) and (S-2): 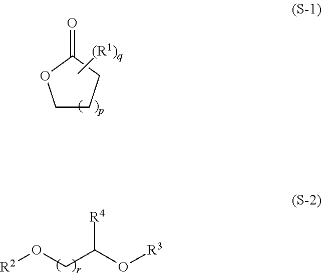
wherein R¹ is hydrogen, hydroxyl, or an optionally substituted C₁-C₈ alkyl group, R² to R⁴ are each independently hydrogen or an optionally substituted C₁-C₈ alkyl group, p is an integer of 1 to 3, q is an integer of 0 to 2, and r is an integer of 1 to 3.

2. The method of claim 1 wherein monomer (A) has the formula (A-1), (A-2) or (A-3): 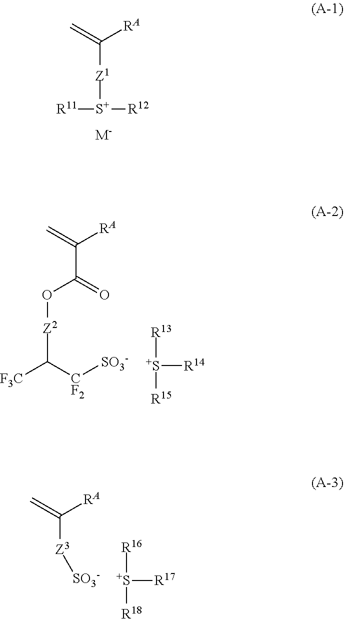
wherein R^{A} is each independently hydrogen or methyl,
Z¹ is a single bond, phenylene, —O—Z¹¹—, —C(═O)—O—Z¹¹— or —C(═O)—NH—Z¹¹—, Z¹¹ is a C₁-C₆ alkanediyl group, C₂-C₆ alkenediyl group or phenylene group, which may contain a carbonyl moiety, ester bond, ether bond or hydroxyl moiety,
Z² is a single bond or —Z²¹—C(═O)—O—, Z²¹ is a C₁-C₂₀ divalent hydrocarbon group which may contain a heteroatom,
Z³ is a single bond, methylene, ethylene, phenylene, fluorinated phenylene, —O—Z³¹, —C(═O)—O—Z³¹— or —C(═O)—NH—Z³¹—, Z³¹ is a C₁-C₆ alkanediyl group, C₂-C₆ alkenediyl group or phenylene group, which may contain a carbonyl moiety, ester bond, ether bond or hydroxyl moiety,
R¹¹ to R¹⁸ are each independently a C₁-C₂₀ monovalent hydrocarbon group which may contain a heteroatom, R¹¹ and R¹² may bond together to form a ring with the sulfur atom to which they are attached, any two or more of R¹³, R¹⁴ and R¹⁵ may bond together to form a ring with the sulfur atom to which they are attached, any two or more of R¹⁶, R¹⁷ and R¹⁸ may bond together to form a ring with the sulfur atom to which they are attached, and
M⁻ is a non-nucleophilic counter ion.

3. The method of claim 1 wherein monomer (B) has the formula (B-1) or (B-2): 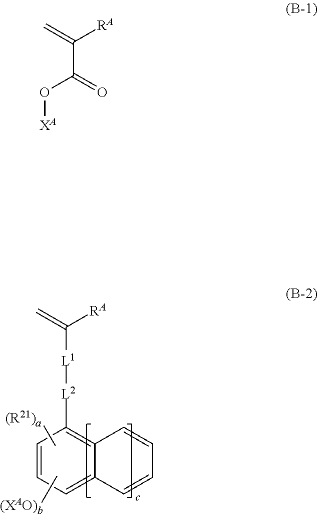
wherein R^{A} is each independently hydrogen or methyl, X^{A} is each independently an acid labile group, R²¹ is each independently hydrogen or a C₁-C₆ alkyl group which may contain an ether bond or carbonyl moiety, L¹ is a single bond, carbonyloxy group or amide group, L² is a single bond or C₁-C₇ alkanediyl group which may contain an ether bond or carbonyl moiety, a is an integer meeting a≤5+2c−b, b is an integer of 1 to 5, and c is an integer of 0 to 2.

4. The method of claim 1 wherein monomer (C) has the formula (C-1): 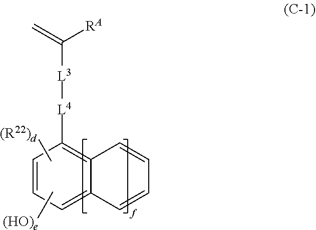
wherein R^{A} is each independently hydrogen or methyl, R²² is each independently hydrogen or a C₁-C₆ alkyl group which may contain an ether bond or carbonyl moiety, L³ is a single bond, carbonyloxy group or amide group, L⁴ is a single bond or C₁-C₇ alkanediyl group which may contain an ether bond or carbonyl moiety, d is an integer meeting d≤5+2f−e, e is an integer of 1 to 5, and f is an integer of 0 to 2.

5. The method of claim 1 wherein the solvent having formula (S-1) is γ-butyrolactone.

6. The method of claim 1 wherein the solvent having formula (S-2) is propylene glycol monomethyl ether.

7. The method of claim 1 wherein the amount of monomer (A) remaining in the reaction solution at the end of polymerization reaction is up to 1.5% by weight based on the polymer.

8. The method of claim 1, further comprising the step of feeding an initiator solution to the reactor independently from the monomer solution.

9. The method of claim 1, further comprising the step of adding the reaction solution to a poor solvent for purification after the polymerization reaction.

10. A polymer comprising recurring units derived from a monomer (A) containing a structure adapted to be decomposed to generate an acid upon light exposure, recurring units derived from a monomer (B) having an acid labile group, and recurring units derived from a monomer (C) having a phenolic hydroxyl group, an amount of residual monomer (A) in the polymer being up to 1.0% by weight.
